(19) United States
(12) Patent Application Publication
(10) Pub. No.: US 2025/0259875 A1
(43) Pub. Date: Aug. 14, 2025

(54) SUBSTRATE PROCESSING METHOD

(71) Applicant: SCREEN Holdings Co., Ltd., Kyoto (JP)

(72) Inventors: Ichiro MITSUYOSHI, Kyoto (JP); Tadashi MAEGAWA, Kyoto (JP); Hidehiko OZAKI, Kyoto (JP); Nozomu NAKAGAWA, Kyoto (JP)

(21) Appl. No.: 19/047,712

(22) Filed: Feb. 7, 2025

(30) Foreign Application Priority Data
Feb. 8, 2024 (JP) 2024-018102

(51) Int. Cl. H01L 21/68; H01L 21/02; H01L 21/311

(52) U.S. Cl. CPC H01L 21/68; H01L 21/02057; H01L 21/31111

(57) ABSTRACT

A substrate processing method including: a first assembly process of positioning a first substrate at a first position among the first position, a second position, a third position, a fourth position, and a fifth position; a second assembly process of positioning a second substrate at the second position by combining a second arrangement with a substrate group; a third assembly process of positioning a third substrate at the third position by combining a third arrangement with the substrate group; a fourth assembly process of positioning a fourth substrate at the fourth position by combining a fourth arrangement with the substrate group; and a fifth assembly process of positioning a fifth substrate at the fifth position by combining a fifth arrangement with the substrate group.

This application claims priority to Japanese Patent Application No. 2024-18102 filed Feb. 8, 2024, the subject matter of which is incorporated herein by reference in entirety.

### BACKGROUND OF THE INVENTION

The present invention relates to a substrate processing method for a semiconductor substrate, a substrate for a flat panel display (FPD) such as a liquid crystal display or an organic electroluminescence (EL) display device, a glass substrate for a photomask, a substrate for an optical disk, and the like.

### DESCRIPTION OF THE RELATED ART

JP H5-175179 A describes a substrate processing apparatus that takes out the same number of substrates from each of two carriers, forms a first substrate group and a second substrate group, inserts the second substrate group into a gap between the respective substrates of the first substrate group to convert the pitch to ½, forms a substrate group of twice the number of substrates, and collectively processes the substrates.

### LIST OF DOCUMENTS

JP H5-175179A

In recent years, there has been a demand for further improvement in efficiency of a substrate processing apparatus. In order to increase the number of substrates to be processed at one time by batch processing, it is necessary to further narrow the arrangement pitch of the substrates. A problem in this case is the orientation of the substrates. That is, for batch processing, it is more suitable from the viewpoint of preventing contamination of the device surface to form a batch lot by arranging substrates by a face-to-face method. In order to arrange the substrates by the face-to-face method with the device surfaces of the substrates facing each other, there is no choice but to combine the substrate arrangement acquired from a first carrier with the substrate arrangement acquired from a second carrier and rotated halfway. Therefore, according to the conventional configuration, although the arrangement pitch of the substrates can be halved, the arrangement pitch of the substrates cannot be further narrowed. When the substrates acquired from the second carrier are inserted into the gap of the substrate arrangement acquired from the first carrier to generate a batch lot, the arrangement pitch of the substrates in the batch lot is naturally determined to be half the original pitch.

The present invention has been made in view of such circumstances, and an object of the present invention is to provide a substrate processing method for efficiently performing substrate processing by narrowing an arrangement pitch of substrates.

### SUMMARY OF THE INVENTION

In order to solve the above problems, the present invention has the following configurations.

That is, according to the present invention, there is provided a substrate processing method for collectively processing a plurality of substrates, the method including: a substrate group generation process of extracting a plurality of substrates from a carrier in which substrates defined on a front surface and a back surface are arranged at a specific pitch, and generating a substrate group in which the substrates are arranged in one direction at a pitch twice the specific pitch; and
a processing process of immersing a batch lot in a processing liquid after generating the batch lot by performing, in an arbitrary order, each of assembly processes including
a first assembly process of positioning a first substrate at a first position among the first position, a second position, a third position, a fourth position, and a fifth position that divide the predetermined interval in the substrate group into six by combining a first arrangement in which the first substrate oriented in an opposite direction to the one direction is arranged at a predetermined interval that is twice the specific pitch with the substrate group,
a second assembly process of positioning a second substrate at the second position by combining a second arrangement in which the second substrate oriented in the one direction is arranged at the predetermined interval with the substrate group,
a third assembly process of positioning a third substrate at the third position by combining a third arrangement in which the third substrate oriented in the opposite direction is arranged at the predetermined interval with the substrate group,
a fourth assembly process of positioning a fourth substrate at the fourth position by combining a fourth arrangement in which the fourth substrate oriented in the one direction is arranged at the predetermined interval with the substrate group, and
a fifth assembly process of positioning a fifth substrate at the fifth position by combining a fifth arrangement in which the fifth substrate oriented in the opposite direction is arranged at the predetermined interval with the substrate group.

### OPERATION AND EFFECT

According to the above-described configuration, the substrate group arranged at the wide arrangement pitch is generated, and the substrates of the first arrangement, the second arrangement, the third arrangement, the fourth arrangement, and the fifth arrangement are inserted into the gap of the substrate group, whereby the arrangement pitch of the substrate group is narrowed. With this configuration, since the opposing relationship between the substrate group and the substrates to be inserted can be freely changed, a new substrate arrangement can be generated by combining the substrate group oriented in one direction, the first arrangement including the substrates oriented in the opposite direction, the second arrangement including the substrates oriented in one direction, the third arrangement including the substrates oriented in the opposite direction, the fourth arrangement including the substrates oriented in one direction, and the fifth arrangement including the substrates oriented in the opposite direction. Therefore, the arrangement pitch of the substrates can be narrowed, and the arrangement direction of the substrates can be made desired.

Furthermore, it is preferable in the above-described configuration that
a front surface of the first substrate in the first assembly process faces a front surface of the substrate group,
a back surface of the second substrate in the second assembly process faces a back surface of the first substrate,
a front surface of the third substrate in the third assembly process faces a front surface of the second substrate,
a back surface of the fourth substrate in the fourth assembly process faces a back surface of the third substrate, and
a front surface of the fifth substrate in the fifth assembly process faces a front surface of the fourth substrate, and a back surface of the fifth substrate faces a back surface of the substrate group.

### OPERATION AND EFFECT

Furthermore, according to the above-described configuration, a front surface of the first substrate in the first assembly process faces a front surface of the substrate group, a back surface of the second substrate in the second assembly process faces a back surface of the first substrate, a front surface of the third substrate in the third assembly process faces a front surface of the second substrate, a back surface of the fourth substrate in the fourth assembly process faces a back surface of the third substrate, and a front surface of the fifth substrate in the fifth assembly process faces a front surface of the fourth substrate, and a back surface of the fifth substrate faces a back surface of the substrate group. According to the present invention, it is possible to generate a substrate arrangement in which the front surface and the back surface are arranged in this manner.

Furthermore, it is preferable in the above-described configuration that,
the first assembly process is performed after half-rotating the first arrangement in which the first substrate oriented in the one direction is arranged at the predetermined interval,
the third assembly process is performed after half-rotating the third arrangement in which the third substrate oriented in the one direction is arranged at the predetermined interval, and
the fifth assembly process is performed after half-rotating the fifth arrangement in which the fifth substrate oriented in the one direction is formed at the predetermined interval.

### OPERATION AND EFFECT

According to the above-described configuration, the first assembly process is performed after half-rotating the first arrangement in which the first substrate oriented in one direction is arranged at a predetermined interval, the third assembly process is performed after half-rotating the third arrangement in which the third substrate oriented in one direction is arranged at a predetermined interval, and the fifth assembly process is performed after half-rotating the fifth arrangement in which the fifth substrate oriented in one direction is arranged at a predetermined interval. In this way, the generation of the substrate arrangement can be completed by receiving the substrate group arranged in one direction from the carrier.

Furthermore, it is preferable in the above-described configuration that,
a first process of collectively acquiring each substrate from a carrier that houses substrates in which substrates in a horizontal posture are arranged in a vertical direction, and
a second process of collectively converting the posture of each substrate from a horizontal posture to a vertical posture are provided, and
the first process and the second process are performed before each assembly process.

### OPERATION AND EFFECT

According to the above-described configuration,
a first process of collectively acquiring each substrate from a carrier that houses substrates in which substrates in a horizontal posture are arranged in a vertical direction, and
a second process of collectively converting the posture of each substrate from a horizontal posture to a vertical posture are performed before each assembly process. With this configuration, the generation of the substrate arrangement can be completed by receiving the substrate group arranged in one direction from the carrier.

Furthermore, it is preferable in the above-described configuration that,
the distance from the first position to the second position is preferably ⅓ of the specific pitch in the carrier.

### OPERATION AND EFFECT

According to the above-described configuration, the distance from the first position to the second position is ⅓ of the specific pitch in the carrier. With this configuration, the pitch of the substrate arrangement to be generated can be ½ or less of the arrangement pitch of the substrates housed in the carrier.

Furthermore, it is preferable in the above-described configuration that,
each assembly process is performed in the order of the first assembly process, the second assembly process, the third assembly process, the fourth assembly process, and the fifth assembly process.

### OPERATION AND EFFECT

According to the above-described configuration, each assembly process is performed in the order of the first assembly process, the second assembly process, the third assembly process, the fourth assembly process, and the fifth assembly process. With this configuration, the substrate arrangement can be easily generated.

Furthermore, it is preferable in the above-described configuration that,
the substrate group is acquired from a first carrier that houses substrates in which substrates in a horizontal posture are arranged in a vertical direction,
the first arrangement is acquired from the first carrier,
the second arrangement is acquired from a second carrier that houses substrates in which substrates in the horizontal posture are arranged in the vertical direction,
the third arrangement is acquired from the second carrier,
the fourth arrangement is acquired from a third carrier that houses substrates in which substrates in the horizontal posture are arranged in the vertical direction, and
the fifth arrangement is preferably acquired from the third carrier.

### OPERATION AND EFFECT

According to the above configuration, the substrate group is acquired from the first carrier, the first arrangement is acquired from the first carrier, the second arrangement is acquired from the second carrier, the third arrangement is acquired from the second carrier, the fourth arrangement is acquired from the third carrier, and the fifth arrangement is acquired from the third carrier. With this configuration, the substrate arrangement can be easily generated from the plurality of carriers.

Furthermore, it is preferable in the above-described configuration that the predetermined interval is equally divided into six by the first position, the second position, the third position, the fourth position, and the fifth position.

### OPERATION AND EFFECT

According to the above configuration, the predetermined interval is equally divided into six by the first position, the second position, the third position, the fourth position, and the fifth position. With this configuration, it is possible to generate a substrate arrangement in which the substrates are arranged more orderly.

Furthermore, it is preferable in the above-described configuration that,
the substrate group generation process extracts every other substrate from the carrier to generate the substrate group.

### OPERATION AND EFFECT

According to the above configuration, every other substrate is extracted from the carrier to generate the substrate group. With this configuration, the substrate group can be easily generated.

Furthermore, it is preferable in the above-described configuration that, in the substrate group generation process, the substrate group is generated by extracting every other substrate in a process of converting the substrates from the horizontal posture to the vertical posture after extracting all the substrates from the carrier.

### OPERATION AND EFFECT

According to the above-described configuration, the substrate group is generated by extracting every other substrate in a subsequent process of converting the substrates from the horizontal posture to the vertical posture after extracting all the substrates from the carrier. With this configuration, the substrate group can be easily generated.

According to the present invention, it is possible to provide a substrate processing method capable of narrowing the arrangement pitch of substrates and efficiently performing substrate processing.

### BRIEF OF DESCRIPTION OF THE DRAWINGS

FIG. 1 is a plan view for explaining an overall configuration of a substrate processing apparatus according to an embodiment;

FIG. 2 is a schematic diagram illustrating a configuration of a carrier according to the embodiment;

FIG. 3 is a perspective view for explaining each unit constituting a transfer block according to the embodiment;

FIG. 4 is a comparative view of a configuration of a carrier and a configuration of a handling robot according to the embodiment;

FIG. 5 is a perspective view illustrating a configuration of an HVC posture converter according to the embodiment;

FIG. 6 is a plan view for explaining a configuration of each rod according to the embodiment;

FIG. 7 is a plan view for explaining the configuration of each rod according to the embodiment;

FIG. 8 is a cross-sectional view for explaining a groove included in a clamping rod according to the embodiment;

FIG. 9 is a schematic diagram illustrating a pusher according to the embodiment;

FIG. 10 is a schematic diagram illustrating a pusher according to the embodiment;

FIG. 11A is a schematic diagram illustrating a batch assembly according to the embodiment;

FIG. 11B is a schematic diagram illustrating a batch assembly according to the embodiment;

FIG. 11C is a schematic diagram illustrating a batch assembly according to the embodiment;

FIG. 11D is a schematic diagram illustrating a batch assembly according to the embodiment;

FIG. 11E is a schematic diagram illustrating a batch assembly according to the embodiment;

FIG. 11F is a schematic diagram illustrating a batch assembly according to the embodiment;

FIG. 11G is a schematic diagram illustrating a batch assembly according to the embodiment;

FIG. 11H is a schematic diagram illustrating a batch assembly according to the embodiment;

FIG. 11I is a schematic diagram illustrating a batch assembly according to the embodiment;

FIG. 11J is a schematic diagram illustrating a batch assembly according to the embodiment;

FIG. 11K is a schematic diagram illustrating a batch assembly according to the embodiment;

FIG. 11L is a schematic diagram illustrating a batch assembly according to the embodiment;

FIG. 11M is a schematic diagram illustrating a batch assembly according to the embodiment;

FIG. 11N is a schematic diagram illustrating a batch assembly according to the embodiment;

FIG. 11O is a schematic diagram illustrating a batch assembly according to the embodiment;

FIG. 11P is a schematic diagram illustrating a batch assembly according to the embodiment;

FIG. 12 is a schematic diagram illustrating a direction of a substrate according to the embodiment;

FIG. 13 is a flowchart illustrating a flow of a substrate according to the embodiment;

FIG. 14 is a flowchart illustrating a flow of a substrate according to the embodiment;

FIG. 15 is a schematic view for explaining a modification of the handling robot according to the embodiment;

FIG. 16A is a schematic diagram illustrating a modification of the batch assembly according to the embodiment;

FIG. 16B is a schematic diagram illustrating a modification of the batch assembly according to the embodiment;

FIG. 16C is a schematic diagram illustrating a modification of the batch assembly according to the embodiment;

FIG. 16D is a schematic diagram for illustrating a modification of the batch assembly according to the embodiment;

FIG. 16E is a schematic diagram illustrating a modification of the batch assembly according to the embodiment; and

FIG. 16F is a schematic diagram illustrating a modification of the batch assembly according to the embodiment.

### DESCRIPTION OF THE PREFERRED EMBODIMENTS

Hereinafter, embodiments of the present invention will be described with reference to the drawings. In the substrate processing apparatus of the embodiment, substrates arranged at a pitch of 10 mm are converted to an arrangement pitch of ⅓ (10/3 mm) to form a batch lot. The formed batch lot is subjected to so-called batch processing in which various substrate processing such as chemical solution immersion processing are collectively performed. When the substrate processing is performed by narrowing the arrangement pitch of the substrates in this manner, a required amount of chemical solution is reduced, so that it is possible to reduce the running cost and perform the substrate processing in consideration of the environment.

The substrate processed by the substrate processing apparatus of the present embodiment has directions defined by the front surface and the back surface. The front surface of the substrate is a device surface to be subjected to film formation processing and exposure processing. The back surface is a surface opposite to the device surface. When the substrate is held in a horizontal posture, the front surface of the substrate faces upward.

### Embodiment

### 1. Overall Configuration

The substrate processing apparatus 1 according to the present invention is configured to perform batch processing. The substrate processing apparatus 1 includes a housing 1A that houses each block. The housing 1A has a substantially rectangular shape in plan view. The housing 1A horizontally arranges and houses a stocker block 3, a transfer block 5, and a processing block 6 from one end side. A load port 9 is provided to protrude from a wall surface on one end side of the housing 1A.

In the present specification, for convenience, a direction in which the stocker block 3, the transfer block 5, and the processing block 6 in the substrate processing apparatus 1 are arranged is referred to as a “front-back direction X”. The front-back direction X extends horizontally. Of the front-back direction X, the direction from the transfer block 5 toward the stocker block 3 in the substrate processing apparatus 1 is referred to as “front side”. A direction opposite to the front is referred to as “back side”. A direction extending horizontally and orthogonal to the front-back direction X is referred to as a “width direction Y”. One direction of the “width direction Y” is referred to as a “right side” for convenience, and the other direction is referred to as a “left side” for convenience. A direction (height direction) orthogonal to the front-back direction X and the width direction Y is referred to as a “vertical direction Z” for convenience. In each drawing, front, back, upper, lower, right, and left are appropriately shown for reference.

### 2. Stocker Block

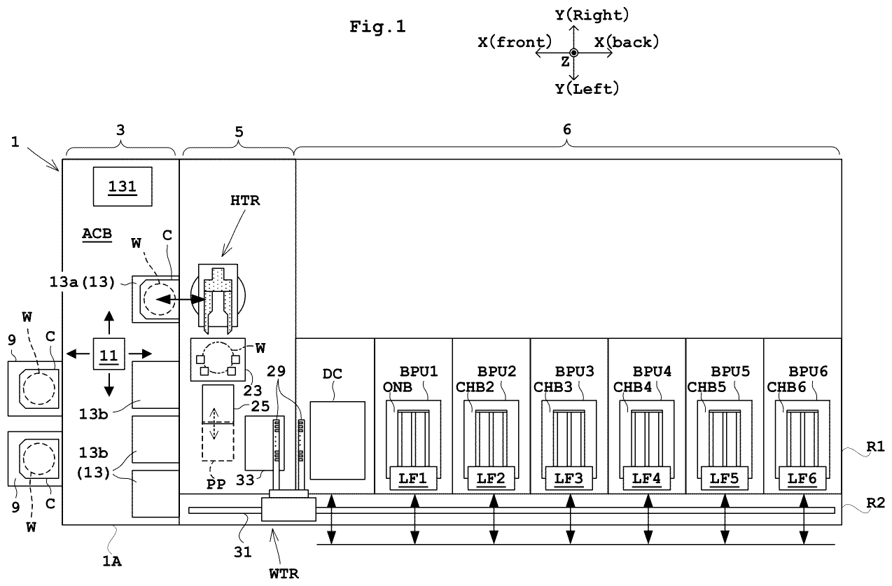

As illustrated in FIG. 1, the stocker block 3 includes a load port 9 which is an entrance when a carrier C for housing a plurality of substrates W in a horizontal posture at predetermined intervals in a vertical direction is input into the block. The load port 9 protrudes from the outer wall of the stocker block 3 extending in the width direction (Y direction).

A plurality of substrates W (for example, 25 sheets) are stacked and housed in one carrier C at regular intervals in the horizontal posture. The carrier C storing the unprocessed substrates W carried into the substrate processing apparatus 1 is first placed on the load port 9.

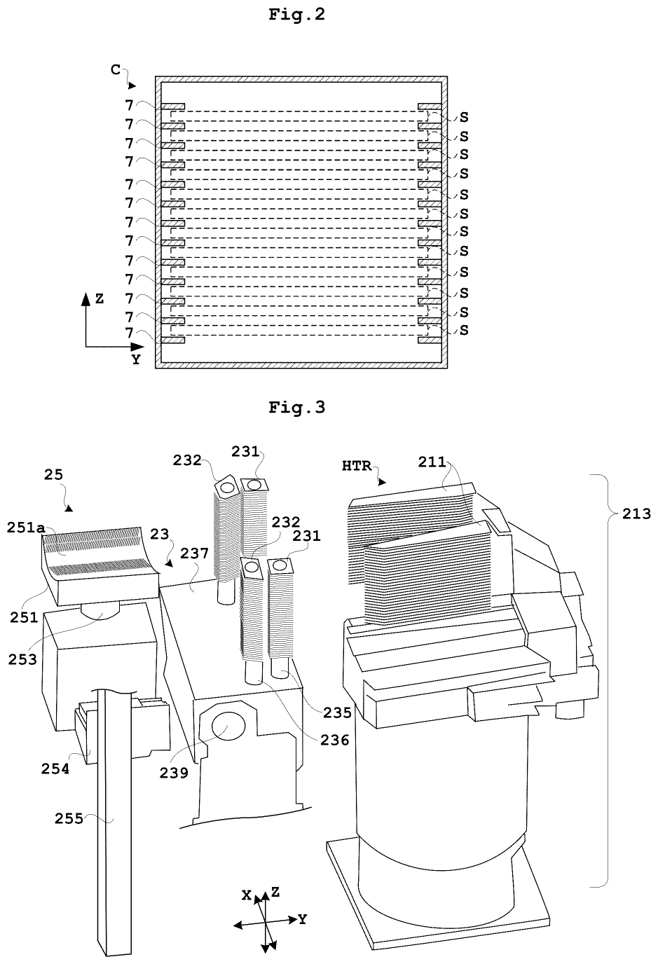

FIG. 2 illustrates a configuration of the carrier C. The carrier C is formed with a plurality of slots S extending in the horizontal direction to hold the surfaces of the substrates W in a state of being separated from each other. The slots S are arranged in the vertical direction at a specific pitch (for example, 10 mm), and the substrates W are accommodated in each of the slots S. 25 slots S are provided in one carrier C. Therefore, in the carrier C, 25 substrates W are arranged in the vertical direction at a specific pitch. A placement plate 7 is positioned to partition each slot S and, together with its paired placement plate 7, supports both ends of each of the substrates W. Therefore, the placement plates 7 are arranged one by one on the side surface of the carrier C and the surface parallel to the side surface. As the carrier C, for example, there is a sealed front opening unify pod (FOUP). In the present invention, an open type container may be employed as the carrier C.

The internal structure of the stocker block 3 will be described. The stocker block 3 includes a conveyance/storage unit ACB that stocks and manages the carrier C. The conveyance/storage unit ACB includes a carrier conveyance mechanism 11 that conveys the carrier C and a shelf 13 on which the carrier C is placed. The number of carriers C that can be stocked by the stocker block 3 is one or more.

The stocker block 3 has a plurality of shelves 13 on which the carrier Cis placed. The shelf 13 is provided on a partition wall separating the stocker block 3 and the transfer block 5. The shelf 13 includes a stock shelf 13b on which the carrier C is simply temporarily placed and a carrier placement shelf 13a on which a first handling robot HTR of the transfer block 5 accesses and from which the substrate is taken out.

The carrier placement shelf 13a has a configuration on which the carrier C can be placed. The carrier placement shelf 13a is configured to place the carrier C, from which the substrates W are to be taken out. In the present embodiment, one carrier placement shelf 13a is provided, but a plurality of carrier placement shelves 13a may be provided. The carrier conveyance mechanism 11 takes in the carrier C housing the unprocessed substrates W from the load port 9 and places the carrier C on the carrier placement shelf 13a for substrate extraction. At this time, the carrier conveyance mechanism 11 can also temporarily place the carrier C on the stock shelf 13b before placing the carrier C on the carrier placement shelf 13a. The number of carrier placement shelves 13a included in the stocker block 3 is 1 or more.

Note that the carrier placement shelf 13a is also configured to place an empty carrier C for housing the processed substrates W. The processed substrates W are housed in the carrier C waiting on the carrier placement shelf 13a. The carrier conveyance mechanism 11 obtains the carrier C storing the processed substrates W from the carrier placement shelf 13a and conveys the carrier C to the load port 9. When the carrier C is conveyed to the load port 9, the carrier conveyance mechanism 11 may temporarily place the carrier C on the shelf 13b for stock.

### 3. Transfer Block

The transfer block 5 is adjacent to the carrier placement shelf 13a. The transfer block 5 is disposed adjacent to the back side of the stocker block 3. The transfer block 5 includes a handling robot HTR that can access the carrier C placed on the carrier placement shelf 13a for substrate extraction, an HVC posture converter 23 that collectively converts the posture of the plurality of substrates W from the horizontal posture to the vertical posture, and a pusher mechanism 25. The HVC posture converter 23 collectively converts the plurality of substrates W from the horizontal posture to the vertical posture. Further, in the transfer block 5, a substrate transfer position PP for transferring a plurality of substrates W to an advance/retract conveyance mechanism WTR provided in a collective conveyance region R2 is set.

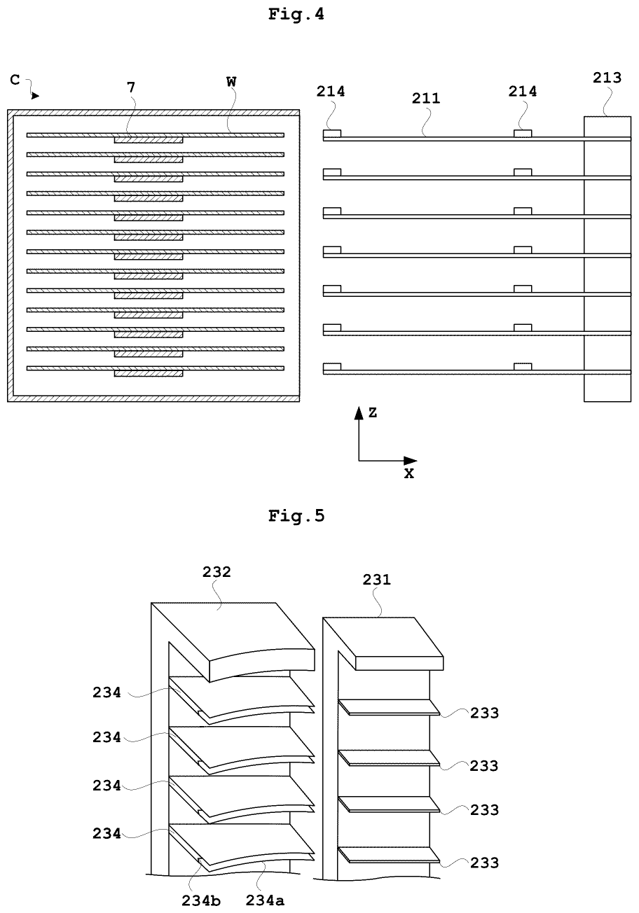

As illustrated in FIG. 3, the handling robot HTR, the HVC posture converter 23, and the pusher mechanism 25 are arranged in this order in the Y direction. The handling robot HTR includes hands 211 capable of gripping substrates W in the horizontal posture. The hand 211 can grip one substrate W. In the handling robot HTR, the hands 211 are arranged in the vertical direction. The handling robot HTR can convey a plurality of substrates W at one time by gripping the substrates with each of the hands 211. The movement support mechanism 213 is a mechanism constituting the handling robot HTR, and is configured to rotate the hands 211 around the vertical axis, raise and lower the hands 211, advance and retract the hands 211 in the front-back direction X, or traverse in the left-right direction Y.

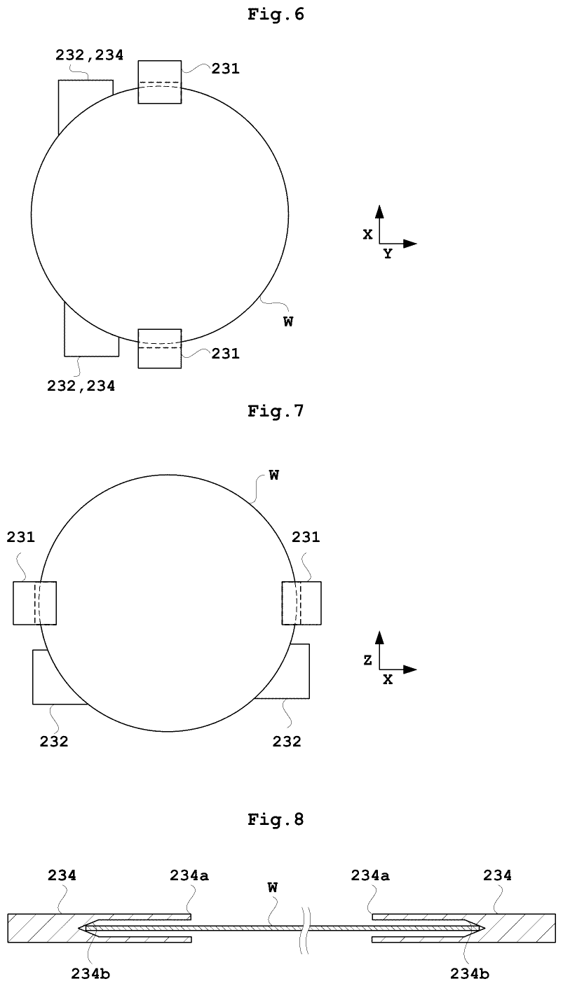

FIG. 4 illustrates a state where the handling robot HTR receives the substrates W in the carrier C using the hands 211. As illustrated in FIG. 4, the hands 211 are arranged in the vertical direction at a pitch twice the arrangement pitch of the slots S provided in the carrier C. That is, the hands 211 are arranged at a pitch of 20 mm. 20 mm corresponds to a predetermined interval of the present invention. The handling robot HTR cannot convey all of the substrates W arranged at intervals of 10 mm on the carrier C at one time. The handling robot HTR is configured to generate a group of substrates arranged with a 20 mm interval by extracting every other substrate W, which is initially arranged at a 10 mm pitch. Since the front surfaces of the substrates W housed in the carrier C all face upward, the substrates W extracted by the handling robot HTR all face upward. Note that each of the hands 211 is provided with a guide 214 that brings a peripheral portion of the substrate into contact with the guide 214. The guide 214 is provided at the distal end portion and the proximal end portion of the pair of blades constituting the hands 211. Therefore, four guides 214 are provided in the hands 211.

The handling robot HTR has 13 hands 211. The handling robot HTR conveys the 25 substrates housed in the carrier C in two separate operations. The handling robot HTR can first convey 12 substrates W and then transport 13 substrates W. Similarly, the handling robot HTR can also convey 13 substrates W first and then 12 substrates W.

The HVC posture converter 23 illustrated in FIG. 3 is configured to convert the substrate W taken out from the carrier C from a horizontal posture to a vertical posture by the handling robot HTR. The HVC posture converter 23 includes a pair of placing rods 231 and a pair of clamping rods 232 extending in the vertical direction (Z direction). The support base 237 has a support surface extending in an XY plane that supports the placing rods 231 and the clamping rods 232. A rotary drive mechanism 239 is configured to rotate the placing rods 231 and the clamping rods 232 together with the support base 237 by 90°. This rotation causes the placing rods 231 and the clamping rods 232 to extend in the left-right direction (Y direction).

The placing rod 231 each includes a rod driving mechanism 235 that rotates about a rotation axis along the extending direction. The pair of placing rods 231 can be synchronously rotated by a pair of rod driving mechanisms 235. The rod driving mechanism 235 can extend and contract the placing rod 231. A specific example when the placing rod 231 is driven by the rod driving mechanism 235 will be described later.

The clamping rod 232 each includes a rod rotary mechanism 236 that rotates about a rotation axis along the extending direction. The pair of clamping rods 232 can be synchronously rotated by a pair of rod rotary mechanisms 236.

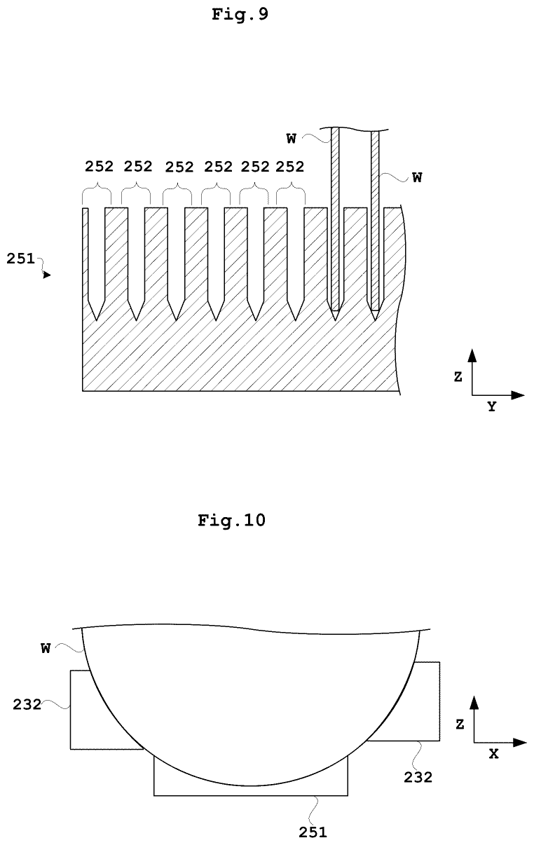

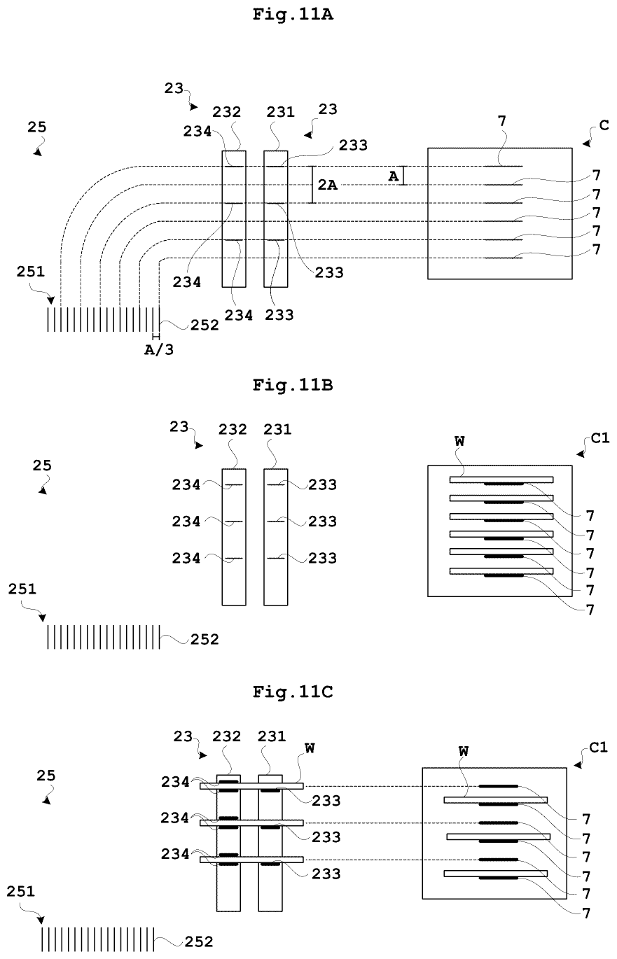

FIG. 5 illustrates flat plates 233 of the placing rod 231. The flat plates 233 are arranged on the placing rod 231 at a pitch of 20 mm in an extending direction of the placing rod 231. Each of the flat plates 233 is a plate extending on a plane orthogonal to the arrangement direction of the flat plates 233, and the substrate W is supported by the placing rod 231 when the end of the substrate W is placed on the upper surface of the flat plate 233. Since it is not possible to hold the entire substrate W only by holding one end portion of the substrate W, two placing rods 231 are provided in the HVC posture converter 23. One end of the substrate W is held by the flat plate 233 of one placing rod 231, and the other end of the substrate W is held by the flat plate 233 of the other placing rod 231. One end and the other end are separated by a distance of the diameter of the substrate W. Therefore, the pair of placing rods 231 is separated by a distance of the diameter of the substrate Was illustrated in FIG. 6. In this way, the substrate W held by the flat plate 233 does not float from the flat plate 233. This is because the weight of the substrate W is symmetrically applied to the flat plate 233, so that the weight of the substrate W in the flat plate 233 is balanced between the left and right. The pair of placing rods 231 is parallel to each other.

FIG. 5 illustrates clamping plates 234 of the clamping rod 232. The clamping plate 234 has an arcuate side 234a along the curve of the substrate W, and the arcuate side 234a is provided with a V groove 234b for clamping the substrate W. Since the substrate W has a shape along the curve of the arcuate side 234a, the substrate W is clamped in the V groove 234b of the arcuate side 234a. The clamping plates 234 are arranged on the clamping rod 232 at a pitch of 20 mm in the extending direction of the clamping rod 232. Each of the clamping plates 234 is a plate extending on a plane orthogonal to the arrangement direction of the clamping plates 234, and a part of the substrate W is fitted into the V groove 234b of the arcuate side 234a, so that the substrate W is clamped by the clamping rod 232.

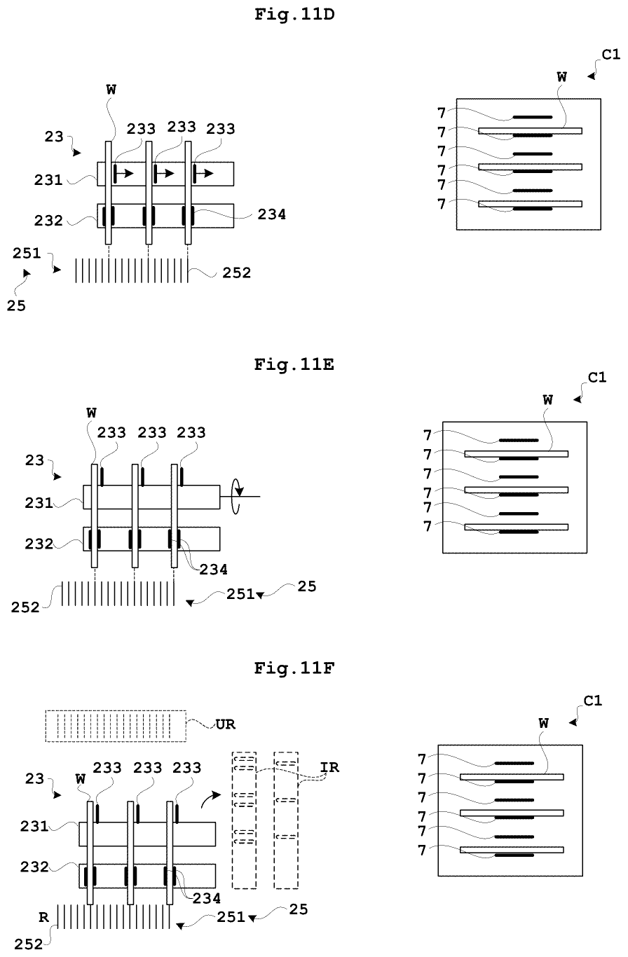

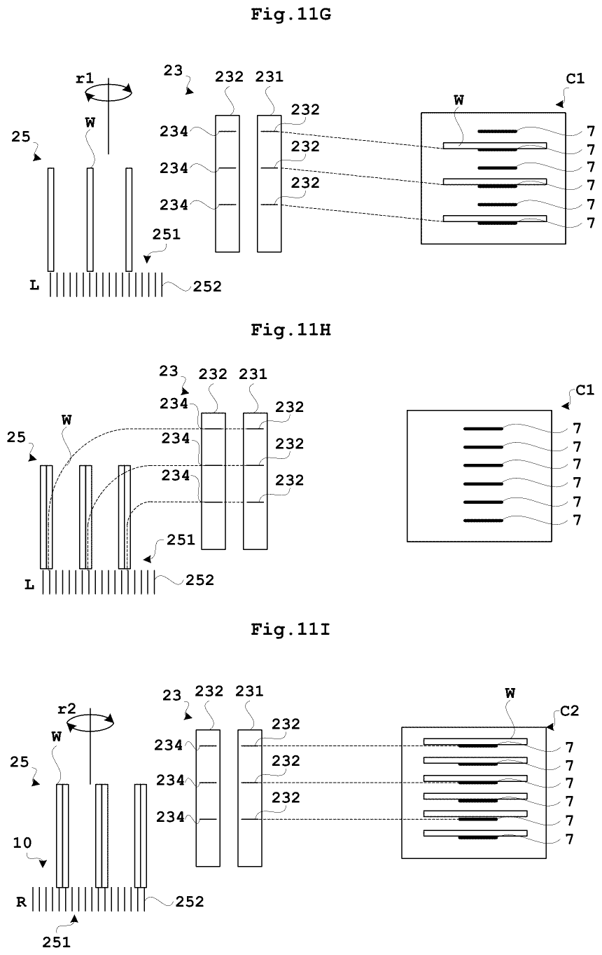

Note that, since it is not possible to realize the clamping of the entire substrate W only by clamping a part of the substrate W, two clamping rods 232 are provided in the HVC posture converter 23. A part of the substrate W is clamped by the clamping plate 234 of one clamping rod 232, and a part of the substrate W is clamped by the clamping plate 234 of the other clamping rod 232. The pair of clamping rods 232 is separated by a distance shorter than the diameter of the substrate W. Since the pair of clamping rods 232 is configured to clamp the substrate W in the vertical posture, it is sufficient that the pair of clamping rods 232 is configured to clamp the lower side of the substrate W, and it is not necessary to separate the pair of clamping rods 232 by the diameter of the substrate W unlike the placing rod 231. Nevertheless, as illustrated in FIG. 7, since the clamping rod 232 is disposed at a position shifted from the bottom portion of the substrate W in the vertical posture, two of a rod for clamping a portion on the right side as viewed from the bottom portion of the substrate W and a rod for clamping a portion on the left side as viewed from the bottom portion of the substrate W are required. As illustrated in FIG. 8, the two clamping rods 232 clamp the substrate W from both sides by the V groove 234b of the clamping plate 234. The pair of clamping rods 232 is parallel to each other.

The pusher mechanism 25 in FIG. 3 includes a pusher 251 capable of horizontally arranging substrates W in a vertical posture. The pusher 251 is a half-pipe type along the curve of the bottom portion of the substrate W. In the pusher 251 in the initial state, the U groove 251a constituting the half-pipe extends in the left-right direction Y. The pusher 251 in this state can receive the substrate W from the HVC posture converter 23.

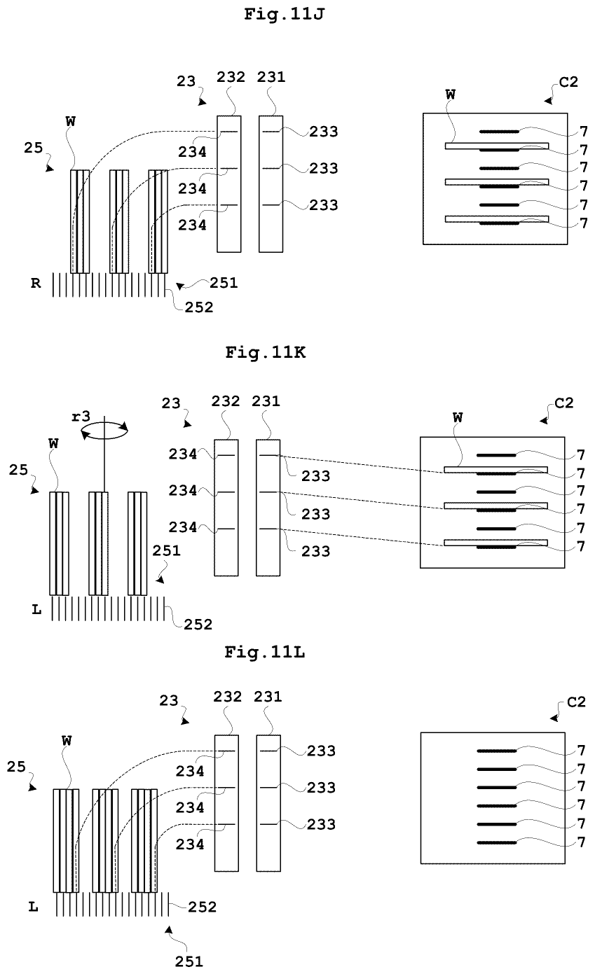

FIG. 9 is a cross-sectional view for explaining the configuration of the pusher 251. The pusher 251 has a plurality of V-shaped clamping grooves 252. The clamping grooves 252 are arranged in the extending direction of the U groove described with reference to FIG. 7. An arrangement pitch of the clamping grooves 252 is 10/3 mm. As illustrated in FIG. 9, one substrate W is clamped by each of the clamping grooves 252.

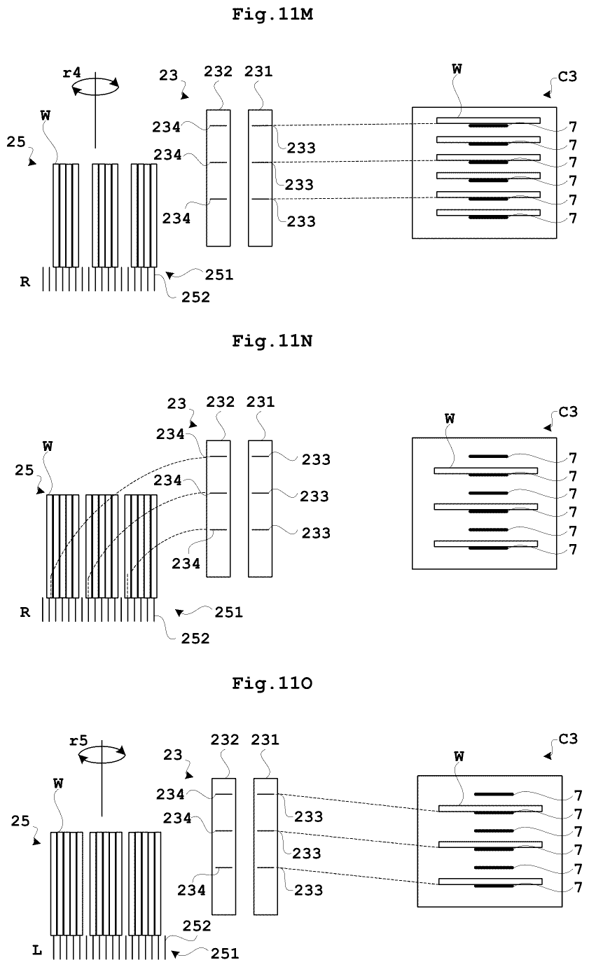

FIG. 10 illustrates a relationship between the pair of clamping rods 232 and the pusher 251. Unlike the state of FIG. 3, the pair of clamping rods 232 in FIG. 10 is tilted by 90° together with the support base 237 by the rotary drive mechanism 239. Therefore, the clamping rod 232 in FIG. 10 extends in the horizontal direction. As can be seen with reference to FIG. 10, the pusher 251 is at a position sandwiched between the pair of clamping rods 232 in the front-back direction X. Therefore, the pair of clamping rods 232 and the pusher 251 do not interfere with each other, and can cooperatively clamp the substrate W in the vertical posture.

The pusher rotation mechanism 253 in FIG. 3 can rotate the pusher 251 by at least 180°. The pusher rotation mechanism 253 can rotate the pusher 251 in the initial state to orient the pusher 251 in the opposite direction, or can rotate the pusher 251 oriented in the opposite direction to return the pusher 251 to the initial state. The pusher shift mechanism 254 can reciprocate the pusher 251 in the initial state in the left-right direction Y. The pusher shift mechanism 254 can bring the pusher 251 close to the HVC posture converter 23 or can bring the pusher 251 close to the advance/retract conveyance mechanism WTR.

A pusher lifting mechanism 255 can raise the pusher 251 at the initial position to the upper position. The pusher lifting mechanism 255 can also return the pusher 251 in the upper position to the initial position.

### 4. Pitch Change in Transfer Block

In the substrate processing apparatus of the present embodiment, since the arrangement pitch of the substrates W can be changed in the transfer block 5, this point will be described. The substrates W arranged at a pitch of 10 mm in the carrier C are first arranged at a pitch of 20 mm in the transfer block 5, and then rearranged at a pitch of 10/3 mm. Hereinafter, this configuration will be specifically described.

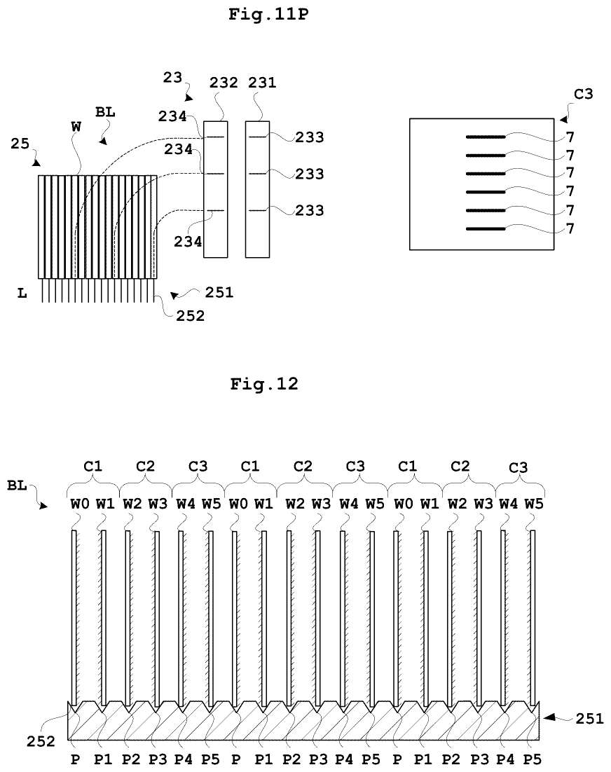

FIG. 11A compares the arrangement pitch of the substrates in each configuration. In the carrier C, the placement plates 7 constituting the slots S are arranged at a pitch of 10 mm. The placement plates 7 are arranged in the vertical direction on one surface of the carrier C, and are arranged in the vertical direction on the other surface of the carrier C. Both ends of the substrate W are placed on the pair of placement plates 7 facing each other, so that the substrate W is held by the carrier C.

On the other hand, flat plates 233 are arranged at a pitch of 20 mm on the placing rod 231 in the HVC posture converter 23. Therefore, assuming that the arrangement pitch of the placement plates 7 of the carriers C is A, the arrangement pitch of the flat plates 233 is 2 A. That is, the pair of placing rods 231 can hold only about half, that is, 13 substrates W out of 25 substrates housed in the carrier C at one time.

Similarly, the clamping plates 234 are arranged at a pitch of 20 mm on the clamping rod 232 in the HVC posture converter 23. Therefore, assuming that the arrangement pitch of the placement plates 7 of the carriers C is A, the arrangement pitch of the clamping plates 234 is 2 A. That is, the pair of clamping rods 232 can hold only about half, that is, 13 substrates W out of 25 substrates housed in the carrier C at one time.

FIG. 11B schematically illustrates a state in which 25 substrates W are arranged on the carrier C. Since three carriers C of different individuals appear in the following description, the carrier C in FIG. 11B is referred to as a first carrier C1. In the first carrier C1, 25 substrates W are arranged at a pitch of 10 mm.

FIG. 11C illustrates a state in which some of the substrates W housed in the first carrier C1 are transferred to the HVC posture converter 23 by the handling robot HTR. The handling robot HTR has hands 211 arranged in the vertical direction at a pitch of 20 mm. Therefore, the handling robot HTR can hold only about half of the substrates W in the first carrier C1 at one time. The handling robot HTR extracts every other substrate W in the first carrier C1 and transfers the substrate W to the HVC posture converter 23. Then, as illustrated in FIG. 6, both ends of the substrate W are supported by the pair of placing rods 231.

At this time, the peripheral edge portion of the substrate W is in contact with each of the clamping plates 234 of the pair of clamping rods 232. Specifically, the peripheral edge portion of the substrate W is fitted into the V groove of the clamping plate 234. Therefore, even if the support base 237 is rotated by 90° in this state, since the substrate W is clamped by the V groove 234b of the clamping plate 234, the substrate W does not slide down from the HVC posture converter 23.

FIG. 11C also illustrates a state in which the placing rod 231 supports the substrate W by the flat plate 233. Similarly, FIG. 11C illustrates a state in which the clamping rod 232 clamps the substrate W with the clamping plate 234.

FIG. 11D illustrates a state when the rotary drive mechanism 239 in the HVC posture converter 23 operates. By this operation, the support base 237 is rotated by 90°, and the placing rod 231 and the clamping rod 232 are in a state of extending horizontally. Then, the load of the substrate W is transferred from the placing rod 231 to the clamping rod 232, and the flat plate 233 of the placing rod 231 is brought into a state of only being in contact with the substrate W. FIG. 11D illustrates a state where placing rod 231 is contracted by rod driving mechanism 235. When the placing rod 231 contracts (slightly displaces and moves so as to be retracted into the support base 237), the flat plate 233 separates from the substrate W. Even when such an operation is performed, since the substrate W is supported by the clamping rod 232, the substrate W does not move along with the movement of the flat plate 233.

By separating the flat plate 233 from the substrate W, even if the substrate W clamped by the clamping rod 232 is lifted by the pusher 251, the flat plate 233 does not damage the back surface of the substrate W.

FIG. 11E illustrates a state when the placing rod 231 is rotated by 90° by rod driving mechanism 235. The flat plate 233 of the placing rod 231 faces upward by the rotation of the placing rod 231. This movement of the flat plate 233 is performed above the pusher 251. The placing rod 231 approaches the pusher 251 together with the substrate W clamped by the clamping rod 232, but at that time, the flat plate 233 does not collide with the substrate W held by the pusher 251. Since the pusher 251 in FIG. 11E does not clamp the substrate W, the rotation operation of the flat plate 233 can be omitted.

FIG. 11F illustrates a state when the pusher 251 subsequently rises. Then, the bottom portion of the substrate W clamped by the clamping rod 232 is fitted into the clamping groove 252 of the pusher 251. When the pusher 251 further rises in this state, the substrate W is removed from the clamping plate 234 of the clamping rod 232. In this manner, the substrate W is transferred from the HVC posture converter 23 to the pusher mechanism 25.

Thereafter, the pusher 251 rises to an upper position UR set above the placing rod 231. The pusher 251 located in the upper position UR does not collide with the placing rod 231 returned to the upright state. FIG. 11F also illustrates a state in which the placing rod 231 and the clamping rod 232 are moved to a virtual position IR indicated by broken lines by the rotary drive mechanism 239. At this time, the placing rod 231 that has contracted returns to the original stretched state. In addition, placing rod 231 reversely rotates to return to the original state described in FIG. 11C.

In this way, the substrates W arranged at a pitch of 20 mm are transferred from the HVC posture converter 23 to the pusher mechanism 25. The clamping groove 252 in the pusher 251 at this time includes a groove that clamps the substrate W and an empty groove that does not clamp the substrate W. The grooves that clamp the substrate W are separated from each other by 6 times the arrangement pitch of the clamping grooves 252. This is because the arrangement pitch of the clamping grooves 252 is 10/3 mm. 20 mm, which is the arrangement pitch of the substrates W, corresponds to exactly 6 times the arrangement pitch of the clamping groove 252. At this time, the substrates W arranged in the pusher 251 are referred to as an initial substrate group or simply as an initial substrate W0 for convenience of description. The initial substrate group corresponds to the substrate group of the present invention.

FIG. 11G illustrates a state when the pusher 251 that has moved down and returned to the initial position is half-rotated by the pusher rotation mechanism 253. The pusher 251 facing the left is referred to as an L state. On the other hand, the pusher 251 in FIG. 11F is in an R state facing the right. The half rotation in FIG. 11G is referred to as a first half rotation r1. FIG. 11G also illustrates a state in which the substrates W arranged at a pitch of 20 mm remaining in the first carrier C1 are conveyed to the HVC posture converter 23 by broken lines. This conveyance is realized by the handling robot HTR having hands 211 arranged at a pitch of 20 mm.

FIG. 11H illustrates a state in which the substrate W held by the HVC posture converter 23 is then transferred to the pusher 251. At this time, the tilting of the placing rod 231 and the clamping rod 232 and the contraction of the placing rod 231 described with reference to FIG. 11D are executed, which have already been specifically described. Similarly, in FIG. 11H, the rotation of the placing rod 231 described with reference to FIG. 11E, the fitting of the substrate W into the pusher 251 described with reference to FIG. 11F, the rising and lowering of the pusher 251, the rising operation of the placing rod 231 and the clamping rod 232, the extending operation of the placing rod 231, and the reverse rotation operation of the placing rod 231 are also omitted.

As can be seen with reference to FIG. 11H, also in this case, the substrates W arranged at a pitch of 20 mm are transferred to the pusher 251 without changing the pitch. When the substrate W is transferred from the HVC posture converter 23 to the pusher mechanism 25, the substrate W is transferred to one of the clamping grooves 252 of the pusher 251. Among the clamping grooves 252, the clamping groove 252 in which the initial substrate group has been already fitted cannot clamp the substrate W any more. Therefore, the substrates W held by the HVC posture converter 23 are conveyed to a position shifted by one pitch in the arrangement of the clamping grooves 252 from the initial substrate group, and are fitted into the clamping grooves 252 on that spot. Such positioning of the substrates W and the pusher 251 is realized by the pusher shift mechanism 254.

In this way, the substrates W arranged at a pitch of 20 mm are transferred from the HVC posture converter 23 to the pusher mechanism 25. In the pusher 251 at this time, a region in which two clamping grooves 252 that clamp the substrate W are continuous and a region in which four empty grooves that do not clamp the substrate W are continuous are alternately arranged. The substrates W newly arranged in the pusher 251 in FIG. 11H are referred to as a first arrangement or simply as a first substrate W1 for convenience of description.

FIG. 11I illustrates a state in which the pusher 251 is then half-rotated by the pusher rotation mechanism 253. The pusher 251 at this time is in the R state. The half rotation in FIG. 11I is referred to as a second half rotation r2. FIG. 11G also illustrates a state in which the substrates W are conveyed from the second carrier C2 to the HVC posture converter 23 by broken lines. The second carrier C2 is a new carrier that the carrier conveyance mechanism 11 has transported to the carrier placement shelf 13a instead of the empty first carrier C1. 25 substrates W arranged at a pitch of 10 mm are housed in the second carrier C2. The substrates W arranged at a pitch of 20 mm are extracted from the second carrier C2 and conveyed to the HVC posture converter 23. This conveyance is realized by the handling robot HTR having hands 211 arranged at a pitch of 20 mm.

FIG. 11J illustrates a state in which the substrate W held by the HVC posture converter 23 is then transferred to the pusher 251. Specific operations such as tilting of the placing rod 231 and the clamping rod 232 described with reference to FIG. 11D executed at that time will be omitted as in FIG. 11H.

As can be seen with reference to FIG. 11J, also in this case, the substrates W arranged at a pitch of 20 mm are transferred to the pusher 251 without changing the pitch. Among the clamping grooves 252 included in the pusher 251, the clamping grooves 252 in which the substrates W of the initial substrate group and the first arrangement are already fitted cannot clamp the substrates W any more. Therefore, the substrates W held by the HVC posture converter 23 are conveyed from the substrate W in the first arrangement to a position shifted by one pitch in the arrangement of the clamping grooves 252, and are fitted into the clamping grooves 252 on the spot. Such positioning of the substrates W and the pusher 251 is realized by the pusher shift mechanism 254.

In this way, the substrates W arranged at a pitch of 20 mm are transferred from the HVC posture converter 23 to the pusher mechanism 25. In the pusher 251 at this time, a region in which three clamping grooves 252 that clamp the substrate W are continuous and a region in which three empty grooves that do not clamp the substrate W are continuous are alternately arranged. The substrates W newly arranged in the pusher 251 in FIG. 11J are referred to as a second arrangement or simply as a second substrate W2 for convenience of description.

FIG. 11K illustrates a state in which the pusher 251 is then half-rotated by the pusher rotation mechanism 253. The pusher 251 at this time is in the L state. The half rotation in FIG. 11K is referred to as a third half rotation r3. FIG. 11K also illustrates a state in which the substrates W remaining in the second carrier C2 are conveyed to the HVC posture converter 23 by broken lines. The substrates W remaining in the second carrier C2 are arranged at a pitch of 20 mm. This conveyance is realized by the handling robot HTR having hands 211 arranged at a pitch of 20 mm.

FIG. 11L illustrates a state in which the substrates W held by the HVC posture converter 23 are then transferred to the pusher 251. Specific operations such as tilting of the placing rod 231 and the clamping rod 232 described with reference to FIG. 11D executed at that time will be omitted as in FIG. 11H.

As can be seen with reference to FIG. 11L, also in this case, the substrates W arranged at a pitch of 20 mm are transferred to the pusher 251 without changing the pitch. Among the clamping grooves 252 included in the pusher 251, the clamping grooves 252 in which the substrates W of the initial substrate group, the first arrangement, and the second arrangement are already fitted cannot clamp the substrates W any more. Therefore, the substrates W held by the HVC posture converter 23 are conveyed from the substrates W in the second arrangement to a position shifted by one pitch in the arrangement of the clamping grooves 252, and are fitted into the clamping grooves 252 on the spot. Such positioning of the substrates W and the pusher 251 is realized by the pusher shift mechanism 254.

In this way, the substrates W arranged at a pitch of 20 mm are transferred from the HVC posture converter 23 to the pusher mechanism 25. In the pusher 251 at this time, a region in which four clamping grooves 252 that clamp the substrates W are continuous and a region in which two empty grooves that do not clamp the substrates W are continuous are alternately arranged. The substrates W newly arranged in the pusher 251 in FIG. 11L are referred to as a third arrangement or simply as a third substrate W3 for convenience of description.

FIG. 11M illustrates a state in which the pusher 251 is then half-rotated by the pusher rotation mechanism 253. The pusher 251 at this time is in the R state. The half rotation in FIG. 11M is referred to as a fourth half rotation r4. FIG. 11M also illustrates a state in which the substrates W are conveyed from the third carrier C3 to the HVC posture converter 23 by broken lines. The third carrier C3 is a new carrier that the carrier conveyance mechanism 11 has transported to the carrier placement shelf 13a instead of the empty second carrier C2. 25 substrates W arranged at a pitch of 10 mm are housed in the third carrier C3. The substrates W arranged at a pitch of 20 mm are extracted from the third carrier C3 and conveyed to the HVC posture converter 23. This conveyance is realized by the handling robot HTR having hands 211 arranged at a pitch of 20 mm.

FIG. 11N illustrates a state in which the substrates W held by the HVC posture converter 23 are then transferred to the pusher 251. Specific operations such as tilting of the placing rod 231 and the clamping rod 232 described with reference to FIG. 11D executed at that time will be omitted as in FIG. 11H.

As can be seen with reference to FIG. 11N, also in this case, the substrates W arranged at a pitch of 20 mm are transferred to the pusher 251 without changing the pitch. Among the clamping grooves 252 included in the pusher 251, the clamping grooves 252 in which the substrates W of the initial substrate group, the first arrangement, the second arrangement, and the third arrangement are already fitted cannot clamp the substrates W any more. Therefore, the substrates W held by the HVC posture converter 23 are conveyed from the substrates W in the third arrangement to a position shifted by one pitch in the arrangement of the clamping grooves 252, and are fitted into the clamping grooves 252 on the spot. Such positioning of the substrates W and the pusher 251 is realized by the pusher shift mechanism 254.

In this way, the substrates W arranged at a pitch of 20 mm are transferred from the HVC posture converter 23 to the pusher mechanism 25. The clamping groove 252 in the pusher 251 at this time includes a groove that clamps the substrate W and an empty groove that does not clamp the substrate W. The empty grooves are separated from each other by 6 times the arrangement pitch of the clamping grooves 252. The substrates W newly arranged in the pusher 251 in FIG. 11N are referred to as a fourth arrangement or simply as a fourth substrate W4 for convenience of description.

FIG. 11O illustrates a state in which the pusher 251 is then half-rotated by the pusher rotation mechanism 253. The pusher 251 at this time is in the L state. The half rotation in FIG. 11O is referred to as a fifth half rotation r5. FIG. 11O also illustrates a state in which the substrates W remaining in the third carrier C3 is conveyed to the HVC posture converter 23 by broken lines. The substrates W remaining in the third carrier C3 are arranged at a pitch of 20 mm. This conveyance is realized by the handling robot HTR having hands 211 arranged at a pitch of 20 mm.

FIG. 11P illustrates a state in which the substrates W held by the HVC posture converter 23 are then transferred to the pusher 251. Specific operations such as tilting of the placing rod 231 and the clamping rod 232 described with reference to FIG. 11D executed at that time will be omitted as in FIG. 11H.

As can be seen with reference to FIG. 11P, also in this case, the substrates W arranged at a pitch of 20 mm are transferred to the pusher 251 without changing the pitch. Among the clamping grooves 252 included in the pusher 251, the clamping grooves 252 in which the substrates W of the initial substrate group, the first arrangement, the second arrangement, the third arrangement, and the fourth arrangement are already fitted cannot clamp the substrates W any more. Therefore, the substrates W held by the HVC posture converter 23 are conveyed from the substrates W in the fourth arrangement to a position shifted by one pitch in the arrangement of the clamping grooves 252, and are fitted into the clamping grooves 252 on the spot. Such positioning of the substrates W and the pusher 251 is realized by the pusher shift mechanism 254.

In this way, the substrates W arranged at a pitch of 20 mm are transferred from the HVC posture converter 23 to the pusher mechanism 25. The clamping grooves 252 in the pusher 251 at this time all clamp the substrates W. The substrates W newly arranged in the pusher 251 in FIG. 11P are referred to as a fifth arrangement or simply as a fifth substrate W5 for convenience of description.

In this way, 75 substrates W are arranged on the pusher 251 at a pitch of 10/3 mm. A substrate array thus produced is referred to as a batch lot BL.

### 5. Batch Lot Composed of Transfer Block

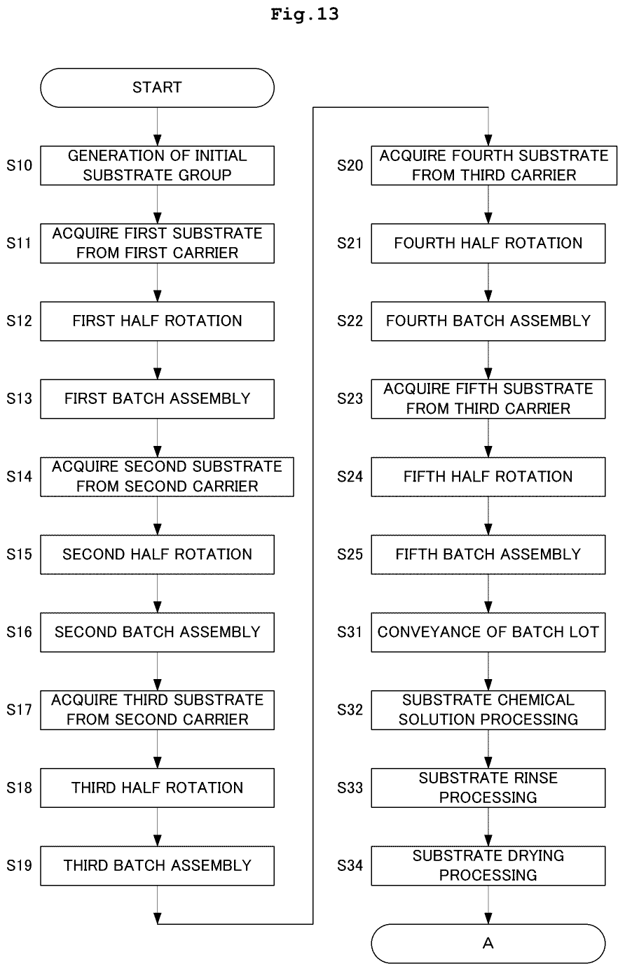

FIG. 12 illustrates the orientation of the substrates W in the batch lot BL. In the batch lot BL, the initial substrate W0 derived from the first carrier C1, the first substrate W1 derived from the first carrier C1, the second substrate W2 derived from the second carrier C2, the third substrate W3 derived from the second carrier C2, the fourth substrate W4 derived from the third carrier C3, and the fifth substrate W5 derived from the third carrier C3 are repeatedly arranged in this order at a 10/3 mm pitch. Among them, the initial substrate W0, the second substrate W2, and the fourth substrate W4 are received by the pusher 251 in the R state facing the right from the HVC posture converter 23, and thus, the directions of these substrates W are aligned in one direction. On the other hand, the first substrate W1, the third substrate W3, and the fifth substrate W5 are received by the pusher 251 in the L state facing the left from the HVC posture converter 23, and thus, the directions of these substrates are aligned in the opposite direction.

That is, the device surface of the first substrate W1 faces the front surface of the initial substrate W0, the back surface of the second substrate W2 faces the back surface of the first substrate W1, the device surface of the third substrate W3 faces the device surface of the second substrate W2, the back surface of the fourth substrate W4 faces the back surface of the third substrate W3, the device surface of the fifth substrate W5 faces the device surface of the fourth substrate W4, and the back surface of the fifth substrate W5 faces the back surface of the initial substrate W0. In this manner, the batch lot BL completed in the pusher 251 is formed by arranging the substrates W in a face-to-face manner.

When the transfer of the substrates W is performed while rotating the pusher 251 as in the present example, the substrates W can be arranged by the face-to-face method based on the initial substrate W0, the first substrate W1, the second substrate W2, the third substrate W3, the fourth substrate W4, and the fifth substrate W5 in which the orientation of the substrates W are all aligned in one direction, and the batch lot BL can be generated.

Next, a relationship between the clamping groove 252 of the pusher 251 and the substrate W will be described. There are six types of positions at which the clamping groove 252 is provided: a reference position P at which the initial substrate W0 is positioned; a first position P1 at which the first substrate W1 is positioned; a second position P2 at which the second substrate W2 is positioned; a third position P3 at which the third substrate W3 is positioned; a fourth position P4 at which the fourth substrate W4 is positioned; and a fifth position P5 at which the fifth substrate W5 is positioned. The reference positions P are arranged at a pitch of 20 mm in the pusher 251, and the first position P1, the second position P2, the third position P3, the fourth position P4, and the fifth position P5 divide 20 mm between the reference positions P into six. Specifically, 20 mm between the reference positions P is equally divided into six by the first position P1, the second position P2, the third position P3, the fourth position P4, and the fifth position P5. Therefore, the distance from the reference position P to the first position P1 is 10/3 mm, which is ⅓ of the arrangement pitch of the substrates W in the carrier C, 10 mm. Similarly, the distance from the first position P1 to the second position P2, the distance from the second position P2 to the third position P3, the distance from the third position P3 to the fourth position P4, the distance from the fourth position P4 to the fifth position P5, and the distance from the fifth position P5 to the reference position P are all 10/3 mm.

The substrate W oriented in one direction is located at the reference position P, the substrate W oriented in the opposite direction is located at the first position P1, the substrate W oriented in one direction is located at the second position P2, the substrate W oriented in the opposite direction is located at the third position P3, the substrate W oriented in one direction is located at the fourth position P4, and the substrate W oriented in the opposite direction is located at the fifth position P5.

### 6. Holding Batch Lot in Transfer Block

The transfer block 5 has two sites capable of holding the batch lot BL. One of them is the pusher 251. The pusher 251 can reciprocate between an initial position where the substrate W can be transferred to and from the HVC posture converter 23 and a transfer position PP where the batch lot BL can be transferred to the advance/retract conveyance mechanism WTR. This reciprocating movement is realized by the pusher shift mechanism 254.

The transfer block 5 includes a lot support 33 as a portion capable of holding the batch lot BL separately from the pusher 251. The lot support 33 serves as a batch lot holding part for temporarily retracting the batch lot BL when congestion of the batch lot BL occurs between the transfer block 5 and the processing block 6.

### 7. Processing Block

Hereinafter, the configuration of the processing block 6 described with reference to FIG. 1 will be described. The processing block 6 is adjacent to the transfer block 5. The processing block 6 performs batch processing on the above-described batch lot BL. The processing block 6 is divided into a batch processing region R1 and the collective conveyance region R2 arranged in the width direction (Y direction). Each region extends in the front-back direction (X direction). Specifically, the batch processing region R1 is disposed inside the processing block 6. The collective conveyance region R2 is adjacent to the batch processing region R1 and is disposed on the leftmost side of the processing block 6.

The batch processing region R1 in the processing block 6 is a rectangular region extending in the front-back direction (X direction). One end side (front side) of the batch processing region R1 is adjacent to the transfer block 5. The other end side of the batch processing region R1 extends in a direction away from the transfer block 5 (backward side). When the batch lot BL is conveyed from the transfer block 5 to the processing block 6, the advance/retract conveyance mechanism WTR included in the processing block 6 is used.

The advance/retract conveyance mechanism WTR collectively conveys a plurality of substrates W in a vertical posture among the transfer block 5, the batch processing units BPU1 to BPU6, and a batch drying chamber DC. The advance/retract conveyance mechanism WTR can hold the batch lot BL including the substrates W arranged at a pitch of 10/3 mm.

The batch processing region R1 includes a batch-type processing unit that performs batch-type processing. Specifically, in the batch processing region R1, the batch drying chamber DC for collectively drying a plurality of substrates W, and a plurality of batch processing units BPU1 to BPU6 for collectively immersing the plurality of substrates W in a direction in which the batch processing region R1 extends are arranged. The batch processing units BPU1 to BPU6 collectively immerse a plurality of substrates in a vertical posture. The arrangement of the batch drying chamber DC and the batch processing units BPU1 to BPU6 will be specifically described. The batch drying chamber DC is adjacent to the transfer block 5 from the rear. The first batch processing unit BPU1 is adjacent to the batch drying chamber DC from the rear. The second batch processing unit BPU2 is adjacent to the first batch processing unit BPU1 from the rear. The third batch processing unit BPU3 is adjacent to the second batch processing unit BPU2 from the rear. The fourth batch processing unit BPU4 is adjacent to the third batch processing unit BPU3 from the rear. The fifth batch processing unit BPU5 is adjacent to the fourth batch processing unit BPU4 from the rear. The sixth batch processing unit BPU6 is adjacent to the fifth batch processing unit BPU5 from the rear. Therefore, the batch drying chamber DC, the first batch processing unit BPU1, the second batch processing unit BPU2, the third batch processing unit BPU3, the fourth batch processing unit BPU4, the fifth batch processing unit BPU5, and the sixth batch processing unit BPU6 are arranged so as to be separated from the transfer block 5 in this order.

Each of the batch processing units BPU1 to BPU6 includes a batch processing tank capable of holding liquid. The batch processing tank is a liquid tank that holds a chemical solution or pure water. The chemical solution is an acidic aqueous solution, for example, a phosphoric acid aqueous solution. In the present specification, the chemical solution and pure water are collectively referred to as a processing liquid. A batch processing tank for holding a chemical solution is referred to as batch chemical solution processing tanks CHB2 to CHB6, and a batch processing tank for holding pure water is referred to as batch rinse processing tank ONB.

Specifically, the second batch processing unit BPU2 includes a batch chemical solution processing tank CHB2 that collectively performs chemical solution processing on the batch lot BL, and a lifter LF2 that raises and lowers the batch lot BL between the substrate transfer position and the chemical solution processing position (see FIG. 2). The substrate transfer position is a position set above the batch chemical solution processing tank CHB2 accessible by the advance/retract conveyance mechanism WTR, and the chemical solution processing position is a position set in the tank of the batch chemical solution processing tank CHB2 capable of immersing the batch lot BL in the chemical solution. The batch chemical solution processing tank CHB2 performs acid processing on the batch lot BL. The acid processing may be a phosphoric acid processing, but may be a processing using another acid. In the phosphoric acid processing, etching processing is performed on a plurality of substrates W constituting the batch lot BL. In the etching processing, for example, the nitride film on the front surface of the substrate W is chemically etched.

The lifter LF2 can hold the batch lot BL including the substrates W arranged at a 10/3 mm pitch. Like the lifter LF2, lifters provided in other processing tanks can also hold the batch lot BL. The batch drying chamber DC can house the batch lot BL.

The batch chemical solution processing tank CHB2 houses an acid solution such as a phosphoric acid solution. The batch chemical solution processing tank CHB2 is provided with a lifter LF2 for moving the batch lot BL up and down. The lifter LF2 moves up and down in the vertical direction (Z direction). Specifically, the lifter LF2 moves up and down between a processing position corresponding to the inside of the batch chemical solution processing tank CHB2 and a delivery position corresponding to the upper side of the batch chemical solution processing tank CHB2. The lifter LF2 holds the batch lot BL including the substrate W in a vertical posture. The lifter LF2 delivers the batch lot BL to and from the advance/retract conveyance mechanism WTR at the delivery position. When the lifter LF2 descends from the delivery position to the processing position in a state of holding the batch lot BL, the entire region of the substrate W is located below the liquid level of the chemical solution. When the lifter LF2 rises from the processing position to the delivery position in a state of holding the batch lot BL, the entire region of the substrate W is located on the liquid level of the chemical solution. The lifter LF2 can collectively immerse the batch lot BL in the batch processing tank. At this time, the lifter LF2 descends from the delivery position to the processing position.

Specifically, the third batch processing unit BPU3 includes a batch chemical solution processing tank CHB3 and a lifter LF3 that raises and lowers the batch lot BL between the substrate transfer position and the chemical solution processing position. The batch chemical solution processing tank CHB3 has the same configuration as the batch chemical solution processing tank CHB2 described above. That is, the batch chemical solution processing tank CHB3 houses the chemical solution described above, and is provided with the lifter LF3. The batch chemical solution processing tank CHB3 performs the same processing as the batch chemical solution processing tank CHB2 on the batch lot BL. The substrate processing apparatus 1 of the present example includes a plurality of processing tanks capable of performing the same chemical solution processing. This is because the phosphoric acid processing takes more time than other processing. The phosphoric acid processing requires a long time (for example, 60 minutes). Therefore, in the apparatus of the present example, the acid processing can be concurrently performed by a plurality of batch chemical solution processing tanks.

The fourth batch processing unit BPU4 to the sixth batch processing unit BPU6 have the same configuration as the second batch processing unit BPU2 and the third batch processing unit BPU3. That is, the fourth batch processing unit BPU4 includes the batch chemical solution processing tank CHB4 and the lifter LF4 that raises and lowers the batch lot BL between the substrate transfer position and the chemical solution processing position. Similarly, the fifth batch processing unit BPU5 includes a batch chemical solution processing tank CHB5 and a lifter LF5 that raises and lowers the batch lot BL between the substrate transfer position and the chemical solution processing position. The sixth batch processing unit BPU6 includes a batch chemical solution processing tank CHB6 and a lifter LF6 that raises and lowers the batch lot BL between the substrate transfer position and the chemical solution processing position. Therefore, the batch lot BL is acid-processed in any one of the batch chemical solution processing tank CHB2 to the batch chemical solution processing tank CHB6. When the chemical solution processing is concurrently performed by the five processing units in this manner, the throughput of the apparatus is increased.

Specifically, the first batch processing unit BPU1 includes a batch rinse processing tank ONB that houses a rinse solution, and a lifter LF1 that raises and lowers the batch lot BL between the substrate transfer position and the rinse position. The substrate transfer position is a position set above the batch rinse processing tank ONB accessible by the advance/retract conveyance mechanism WTR, and the rinse position is a position set in a tank of the batch rinse processing tank ONB capable of immersing the batch lot BL in the rinse solution. The batch rinse processing tank ONB has the same configuration as the batch chemical solution processing tank CHB2 described above. That is, the batch rinse processing tank ONB houses the rinse solution and is provided with the lifter LF1. Unlike other processing tanks, the batch rinse processing tank ONB houses pure water, and is provided for the purpose of cleaning the chemical solution attached to the plurality of substrates W. In the batch rinse processing tank ONB, when the specific resistance of the pure water in the tank increases to a predetermined value, the cleaning processing ends.

As described above, the batch rinse processing tank ONB in the present embodiment is located closer to the transfer block 5 than the batch chemical solution processing tanks CHB2 to CHB6. With this configuration, the mechanisms constituting the transfer block 5 and the batch chemical solution processing tanks CHB2 to CHB6 are separated as much as possible, and the pusher mechanism 25 and the like are not adversely affected by an acid such as phosphoric acid. In addition, by arranging the transfer block 5 and the batch drying chamber DC close to each other, the batch lot BL for which the rinse processing has been finished is conveyed by a short distance and immediately returned to the transfer block 5.

### 8. Collective Conveyance Region in Processing Block

The collective conveyance region R2 in the processing block 6 is a rectangular region extending in the front-back direction (X direction). The collective conveyance region R2 is provided along the outer edge of the batch processing region R1, and has one end side extending to the transfer block 5 and the other end side extending in a direction away from the transfer block 5.

The collective conveyance region R2 is provided with an advance/retract conveyance mechanism WTR that collectively conveys a plurality of substrates W. The advance/retract conveyance mechanism WTR collectively conveys a plurality of substrates W (specifically, batch lots BL) between the substrate transfer position PP defined in the transfer block 5, the lot support 33, the batch drying chamber DC, and each of the batch processing units BPU1 to BPU6. The advance/retract conveyance mechanism WTR is configured to be able to reciprocate in the front-back direction (X direction) across the transfer block 5 and the processing block 6. The advance/retract conveyance mechanism WTR can also enter the substrate transfer position PP and the lot support 33 in the transfer block 5 in addition to the collective conveyance region R2 in the processing block 6.

The advance/retract conveyance mechanism WTR includes a pair of chucks 29 for conveying the batch lot BL. The pair of chucks 29 can be changed to a closed state in which they are close to each other and an open state in which they are separated from each other. The chuck 29 is a member extending in the Y direction in which grooves for gripping the substrate W are arranged at a pitch of 10/3 mm. The pair of chucks 29 is closed to receive the plurality of substrates W constituting the batch lot BL. Then, the pair of chucks 29 is opened to transfer the plurality of substrates W constituting the batch lot BL to another member (the lifter LF1 or the like). The advance/retract conveyance mechanism WTR transfers the batch lot BL between the substrate transfer position PP in the transfer block 5 and the lot support 33. In addition, the advance/retract conveyance mechanism WTR transfers the batch lot BL to and from each of the lifters LF1 to LF6 belonging to the batch processing units BPU1 to BPU6 in the processing block 6 and the batch drying chamber DC.

In the collective conveyance region R2, a guide rail 31 extending in the X direction for guiding the advance/retract conveyance mechanism WTR is provided. The advance/retract conveyance mechanism WTR can advance and retract in the X direction along the guide rail 31. Therefore, the guide rail 31 extends from the processing block 6 to the transfer block 5. More specifically, the guide rail 31 faces the substrate transfer position PP in the transfer block 5 from the Y direction, and faces the sixth batch processing unit BPU6 in the processing block 6 from the Y direction. Besides, the guide rail 31 faces the lot support 33 in the transfer block 5, the batch drying chamber DC in the processing block 6, and the first batch processing unit BPU1 to the sixth batch processing unit BPU6 from the Y direction.

### 9. Other Configurations in Processing Block

The batch drying chamber DC is disposed at a position sandwiched between the first batch processing unit BPU1 and the transfer block 5. The batch drying chamber DC has a drying chamber that accommodates the batch lot BL in which the substrates W in the vertical posture are arranged. The drying chamber includes an inert gas supply nozzle that supplies an inert gas into the chamber, and a vapor supply nozzle that supplies vapor of an organic solvent into the tank. The batch drying chamber DC first supplies an inert gas to the batch lot BL supported in the chamber to replace the atmosphere in the chamber with the inert gas. Then, pressure reduction in the chamber is started. In a state where the inside of the chamber is depressurized, vapor of the organic solvent is supplied into the chamber. The organic solvent is discharged to the outside of the chamber together with moisture adhering to the substrate W. In this way, the batch drying chamber DC performs the drying of the batch lot BL. The inert gas at this time may be, for example, nitrogen, and the organic solvent may be, for example, isopropyl alcohol (IPA).

The carrier placement shelf 13a, the batch drying chamber DC, and the batch processing units BPU1 to BPU6 in the substrate processing apparatus 1 are arranged in the front-back direction. That is, the carrier placement shelf 13a is arranged in front, and the batch drying chamber DC is arranged behind the carrier placement shelf 13a. The batch processing units BPU1 to BPU6 are disposed further behind the batch processing units BPU1 to BPU6. In the substrate processing apparatus 1 of the present embodiment, the layout in the apparatus is optimized so that the moving distance of the advance/retract conveyance mechanism WTR decreases.

### 10. Controller

FIG. 1 can be referred to for the controller 131 included in the substrate processing apparatus 1. Although not illustrated in FIG. 1, the controller 131 is provided with a corresponding storage unit. The controller 131 includes, for example, a central processing unit (CPU). A specific configuration of the controller is not limited, and for example, each controller may be configured by a single processor, or each controller may be configured by an individual processor.

Examples of the control related to the controller 131 include control related to the carrier conveyance mechanism 11, the handling robot HTR, the HVC posture converter 23, the pusher mechanism 25, the advance/retract conveyance mechanism WTR, the batch processing units BPU1 to BPU6, and the batch drying chamber DC. The storage unit houses programs, parameters, and the like related to control. The storage unit may be configured by a single device or may be configured by individual devices corresponding to the respective controllers. In addition, the substrate processing system of the present embodiment has no particular limitation on the configuration of the device that realizes the storage unit.

### 11. Flow of Substrate Processing

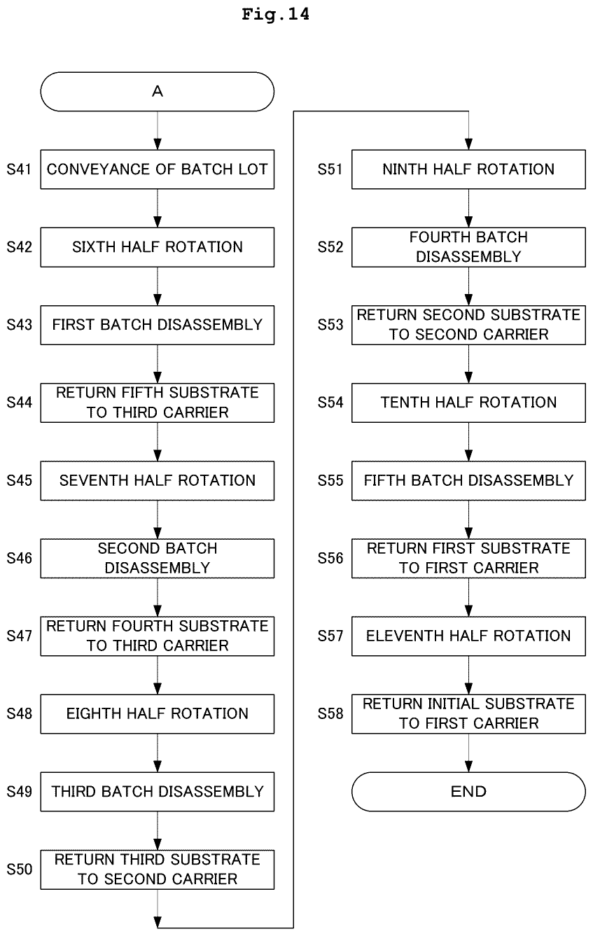

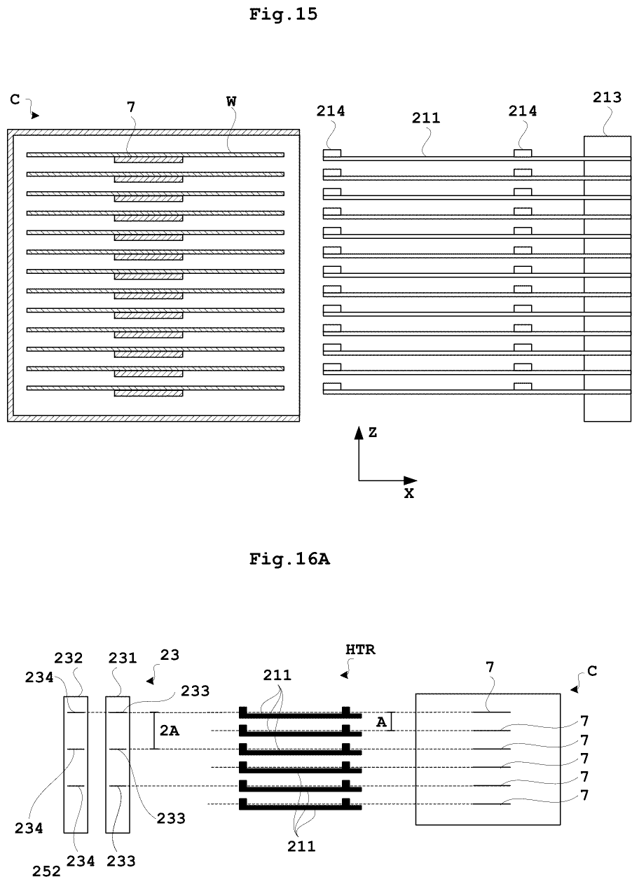

Hereinafter, the flow of the substrate processing of the present example will be described with reference to the flowcharts of FIGS. 13 and 14.

Step S10: Every other initial substrate W0 is extracted by the handling robot HTR from the first carrier C1. The extracted initial substrate W0 is arranged at a pitch of 20 mm. The posture of the initial substrate W0 is converted from a horizontal posture to a vertical posture. The initial substrate W0 in the vertical posture is acquired by the pusher 251. The first carrier C1 corresponds to the first carrier of the present invention.

Step S11: The remaining first substrate W1 is extracted from the first carrier C1 by the handling robot HTR. The first substrate W1 is also arranged at a pitch of 20 mm. The first substrate W1 is acquired by the HVC posture converter 23.

Step S12: A half rotation of the pusher 251 holding the initial substrate group in the vertical posture is executed. As a result, the initial substrate group faces one direction.

Step S13: In the pusher 251, a batch assembly of the initial substrate W0 and the first substrate W1 is performed. The first substrate W1 is positioned at the first position P1 of the pusher 251 by combining the first arrangement in which the first substrate W1 oriented in the opposite direction to one direction are arranged at an interval of 20 mm with the initial substrate group. As a result, the initial substrate W0 and the first substrate W1 are arranged at an interval of 10/3 mm in a state where the device surfaces face each other. Step S13 corresponds to the first assembly process of the present invention.

Step S14: Every other second substrate W2 is extracted from the second carrier C2 by the handling robot HTR. The extracted second substrate W2 is arranged at a pitch of 20 mm. The second substrate W2 is acquired by the HVC posture converter 23. The second carrier C2 corresponds to the second carrier of the present invention. Step S15: A half rotation of the pusher 251 holding the initial substrate W0 and the first substrate W1 is executed.

Step S16: In the pusher 251, a batch assembly of the substrate array including the initial substrate W0 and the first substrate W1 and the second substrate W2 is performed. The second substrate W2 is positioned at the second position P2 of the pusher 251 by combining the second arrangement in which the second substrate W2 oriented in one direction at an interval of 20 mm with the substrate array in the pusher 251. As a result, the first substrate W1 and the second substrate W2 are arranged at an interval of 10/3 mm in a state where the back surfaces face each other. Step S16 corresponds to the second assembly process of the present invention.

Step S17: The remaining third substrate W3 is extracted from the second carrier C2 by the handling robot HTR. The third substrate W3 is arranged at a pitch of 20 mm. The HVC posture converter 23 acquires the third substrate W3.

Step S18: A half rotation of the pusher 251 holding the initial substrate W0, the first substrate W1, and the second substrate 2 is executed.

Step S19: In the pusher 251, a batch assembly of the substrate array including the initial substrate W0, the first substrate W1, and the second substrate W2 and the third substrate W3 is performed. The third substrate W3 is positioned at the third position P3 of the pusher 251 in combination with the third arrangement in which the third substrate W3 oriented in the opposite direction is arranged at an interval of 20 mm and the substrate array in the pusher 251. As a result, the second substrate W2 and the third substrate W3 are arranged at an interval of 10/3 mm in a state where the device surfaces face each other. Step S19 corresponds to the third assembly process of the present invention.

Step S20: Every other fourth substrate W4 is extracted from the third carrier C3 by the handling robot HTR. The extracted fourth substrate W4 is arranged at a pitch of 20 mm. The fourth substrate W4 is acquired by the HVC posture converter 23. The third carrier C3 corresponds to the third carrier of the present invention.

Step S21: A half rotation of the pusher 251 holding the initial substrate W0, the first substrate W1, the second substrate W2, and the third substrate W3 is executed.

Step S22: In the pusher 251, a batch assembly of the substrate array including the initial substrate W0, the first substrate W1, the second substrate W2, and the third substrate W3 and the fourth substrate W4 is performed. The fourth substrate W4 is positioned at the fourth position P4 of the pusher 251 by combining the fourth arrangement in which the fourth substrate W4 oriented in one direction at an interval of 20 mm with the substrate array in the pusher 251. As a result, the third substrate W3 and the fourth substrate W4 are arranged at an interval of 10/3 mm in a state where the back surfaces face each other. Step S22 corresponds to the fourth assembly process of the present invention.

Step S23: The remaining fifth substrate W5 is extracted from the third carrier C3 by the handling robot HTR. The fifth substrate W5 is arranged at a pitch of 20 mm. The fifth substrate W5 is acquired by the HVC posture converter 23.

Step S24: A half rotation of the pusher 251 holding the initial substrate W0, the first substrate W1, the second substrate W2, the third substrate W3, and the fourth substrate W4 is executed.

Step S25: In the pusher 251, a batch assembly of the substrate array including the initial substrate W0, the first substrate W1, the second substrate W2, the third substrate W3, and the fourth substrate W4 and the fifth substrate W5 is performed. The fifth substrate W5 is positioned at the fifth position P5 of the pusher 251 in combination with the fifth arrangement in which the fifth substrate W5 oriented in the opposite direction at an interval of 20 mm and the substrate array in the pusher 251. As a result, the fourth substrate W4 and the fifth substrate W5 are arranged at an interval of 10/3 mm in a state where the device surfaces face each other. Step S25 corresponds to the fifth assembly process of the present invention.

Step S31: The generated batch lot BL is conveyed from the transfer block 5 to the processing block 6 by the advance/retract conveyance mechanism WTR.

Step S32: The batch lot BL is subjected to a chemical solution processing. Step S32 corresponds to a processing process of the present invention.

Step S33: The batch lot BL is subjected to a rinse processing. Step S33 corresponds to a processing process of the present invention.

Step S34: The batch lot BL is subjected to a drying processing.

In this way, the substrate processing is realized in batch lot units.

FIG. 14 illustrates a flowchart when the batch lot BL for which the substrate processing has been completed is returned to the carrier C. The returning operation of the substrate W is basically obtained by reversing the above-described method over time.

Step S41: The batch lot BL subjected to the substrate processing is conveyed from the processing block 6 to the transfer block 5 by the advance/retract conveyance mechanism WTR.

Step S42: The pusher 251 is half-rotated after acquiring the batch lot BL. With this operation, the fifth substrate W5 that has been oriented in the opposite direction is oriented in one direction.

Step S43: The HVC posture converter 23 receives the fifth substrate W5 from the batch lot BL in the pusher 251, and disassembles the batch lot BL.

Step S44: After the posture of the fifth substrate W5 is converted by the HVC posture converter 23, the fifth substrate W5 is returned to the third carrier C3 by the handling robot HTR.

Step S45: The pusher 251 is half-rotated. With this operation, the fourth substrate W4 that has been oriented in the opposite direction is oriented in one direction.

Step S46: The HVC posture converter 23 receives the fourth substrate W4 from the batch lot BL in the pusher 251, and disassembles the batch lot BL.

Step S47: After the posture of the fourth substrate W4 is converted by the HVC posture converter 23, the fourth substrate W4 is returned to the third carrier C3 by the handling robot HTR.

Step S48: The pusher 251 is half-rotated. With this operation, the third substrate W3 that has been oriented in the opposite direction is oriented in one direction.

Step S49: The HVC posture converter 23 receives the third substrate W3 from the batch lot BL in the pusher 251, and disassembles the batch lot BL.

Step S50: After the posture of the third substrate W3 is converted by the HVC posture converter 23, the third substrate W3 is returned to the second carrier C2 by the handling robot HTR.

Step S51: The pusher 251 is half-rotated. By this operation, the second substrate W2 that has been oriented in the opposite direction is oriented in one direction.

Step S52: The HVC posture converter 23 receives the second substrate W2 from the batch lot BL in the pusher 251, and disassembles the batch lot BL.

Step S53: After the posture of the second substrate W2 is changed by the HVC posture converter 23, the second substrate W2 is returned to the second carrier C2 by the handling robot HTR.

Step S54: The pusher 251 is half-rotated. By this operation, the first substrate W1 that has been oriented in the opposite direction is oriented in one direction.

Step S55: The HVC posture converter 23 receives the first substrate W1 from the batch lot BL in the pusher 251, and disassembles the batch lot BL.

Step S56: After the posture of the first substrate W1 is converted by the HVC posture converter 23, the first substrate W1 is returned to the first carrier C1 by the handling robot HTR.

Step S57: The pusher 251 is half-rotated. By this operation, the initial substrate W0 that has been oriented in the opposite direction is oriented in one direction.

Step S58: The HVC posture converter 23 receives the initial substrate W0 from the batch lot BL in the pusher 251. The initial substrate W0 is returned to the first carrier C1 by the handling robot HTR after being posture-converted by the HVC posture converter 23.

### 12. Effects of Present Example

As described above, according to the configuration of the present example, the arrangement pitch of the substrate group is narrowed by acquiring the substrate group arranged at a wide arrangement pitch and inserting the substrates W of the first arrangement, the second arrangement, the third arrangement, the fourth arrangement, and the fifth arrangement into the gap of the substrate groups. With this configuration, since the opposing relationship between the substrate group and the substrate to be inserted can be freely changed, a new batch lot BL can be generated by combining the substrate group oriented in one direction, the first arrangement including the first substrate W1 oriented in the opposite direction, the second arrangement including the second substrate W2 oriented in one direction, the third arrangement including the third substrate W3 oriented in the opposite direction, the fourth arrangement including the fourth substrate W4 oriented in one direction, and the fifth arrangement including the fifth substrate W5 oriented in the opposite direction. Therefore, the arrangement pitch of the substrates W can be narrowed, and the arrangement direction of the substrates W can be made desired.

According to the configuration of the present example, the front surface of the first substrate W1 in step S13 is opposed to the front surface of the initial substrate group, the back surface of the second substrate W2 in step S16 is opposed to the back surface of the first substrate W1, the front surface of the third substrate W3 in step S18 is opposed to the front surface of the second substrate W2, the back surface of the fourth substrate W4 in step S22 is opposed to the back surface of the third substrate W3, the front surface of the fifth substrate W5 in step S25 is opposed to the front surface of the fourth substrate W4, and the back surface of the fifth substrate W5 is opposed to the back surface of the initial substrate group. According to the present example, it is possible to generate the batch lot BL in which the front surface and the back surface are arranged in this manner.

According to the configuration of the present example, step S13 is performed after half-rotating the first arrangement in which the first substrate oriented in one direction is arranged at a predetermined interval, step S18 is performed after half-rotating the third arrangement in which the third substrate oriented in one direction is arranged at a predetermined interval, and step S25 is performed after half-rotating the fifth arrangement in which the fifth substrate oriented in one direction is arranged a predetermined interval. In this way, the generation of the batch lot BL row can be completed by receiving the substrate group arranged in one direction from the carrier C.

According to the configuration of the present example, a first process of collectively acquiring the substrates W from the carrier C housing the substrates W in which the substrates in the horizontal posture are arranged in the vertical direction, and a second process of collectively converting the posture of the substrates W from the horizontal posture to the vertical posture are performed before each assembly process. With this configuration, the generation of the batch lot BL can be completed by receiving the substrate group arranged in one direction from the carrier C.

According to the configuration of the present example, the distance from the first position P1 to the second position P2 is ⅓ of the specific pitch of 10 mm in the carrier C. With this configuration, the pitch of the substrate arrangement to be generated can be ½ or less of the arrangement pitch of the substrates W housed in the carrier C.

According to the configuration of the present example, steps related to the batch assembly is performed in the order of step S13 related to the first substrate W1, step S16 related to the second substrate W2, step S18 related to the third substrate W3, step S22 related to the fourth substrate W4, and step S25 related to the fifth substrate W5. With this configuration, it is easy to generate the batch lot BL.

According to the configuration of the present example, the initial substrate group is acquired from the first carrier C, the first arrangement is acquired from the first carrier C, the second arrangement is acquired from the second carrier C, the third arrangement is acquired from the second carrier C, the fourth arrangement is acquired from the third carrier C, and the fifth arrangement is acquired from the third carrier C. With this configuration, the batch lot BL can be easily generated from the plurality of carriers C.

According to the configuration of the present example, the predetermined interval, 20 mm, is equally divided into six by the first position P1, the second position P2, the third position P3, the fourth position P4, and the fifth position P5. With this configuration, it is possible to generate the batch lot BL in which the substrates W are arranged more orderly.

According to the configuration of the present example, every other substrate W is extracted from the first carrier C1 to generate the initial substrate group. With this configuration, it is easy to generate the initial substrate group.

### 13. Modified Example

The present invention is not limited to the configuration of the above-described embodiment, and modifications can be made as follows.

### Modification 1

According to the above configuration, the batch assembly is performed in the order of the first substrate W1, the second substrate W2, the third substrate W3, the fourth substrate W4, and the fifth substrate W5, but this order can be arbitrary. In particular, if the order is changed so that the batch assembly is correctively performed for the first substrate W1, the third substrate W3, and the fifth substrate W5, the half-rotating operation of the pusher 251 can be partially omitted.

### Modification 2

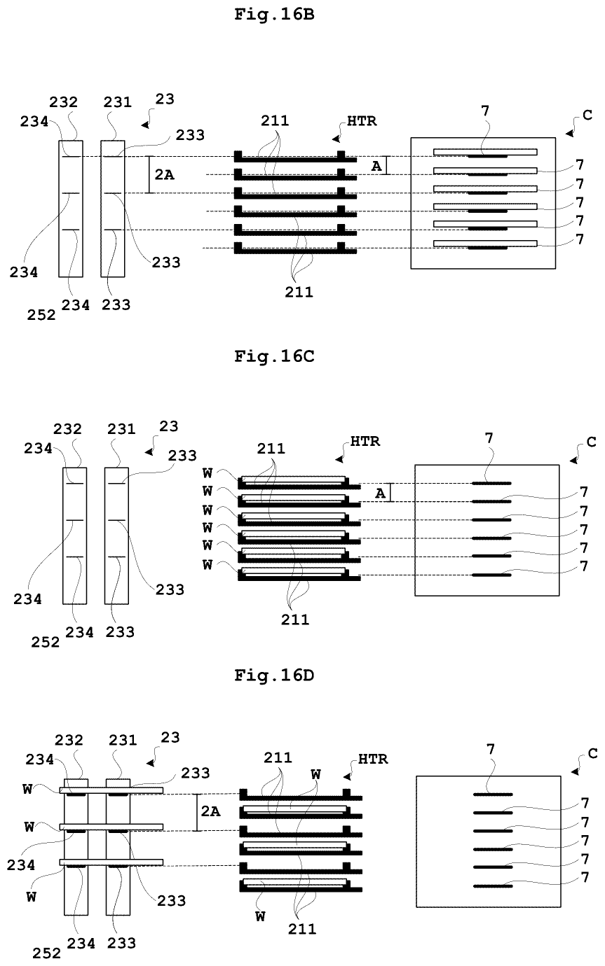

The handling robot HTR having the above-described configuration is configured to acquire only about half of the number of substrates W in the carrier C at one time, but the present invention is not limited to this configuration. As shown in FIG. 15, the present invention can also be applied to a substrate processing apparatus having a handling robot HTR in which hands 211 are arranged at a pitch of 10 mm.

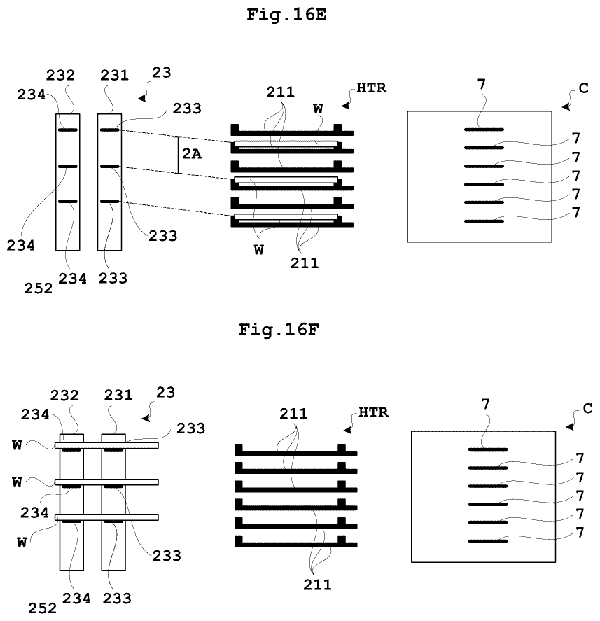

Hereinafter, a method of conveying the substrate W in the present modification will be described. FIG. 16A compares the arrangement pitch of the substrates in each configuration. In the carrier C, the placement plates 7 constituting the slots S are arranged at a pitch of 10 mm.

On the other hand, the HVC posture converter 23 can hold only about half, that is, 13 substrates W out of 25 substrates housed in the carrier C at one time. This is because the flat plates 233 of the placing rod 231 are arranged at a pitch of 20 mm. This is also because the clamping plates 234 of the clamping rods 232 are arranged at a pitch of 20 mm.

The handling robot HTR of the present modification can hold 25 substrates W housed in the carrier C at one time. This is because the hands 211 in the handling robot HTR are arranged at a pitch of 10 mm.

According to the present modification, although the handling robot HTR can hold 25 substrates housed in the carrier C at a time, the handling robot HTR cannot transfer the held substrates W to the HVC posture converter 23 at one time. Therefore, the handling robot HTR of the present modification has a configuration in which about half of the substrates W housed in the carrier C is transferred to the HVC posture converter 23, and the remaining half is temporarily held. The remaining substrates W held by the handling robot HTR is transferred to the HVC posture converter 23 at another coming opportunity.

FIG. 16B schematically illustrates a state in which 25 substrates W are arranged on the carrier C. In the carrier C, 25 substrates W are arranged at a pitch of 10 mm.

FIG. 16C illustrates a state in which the handling robot HTR extracts all of the substrates W housed in the carrier C from the carrier C. The handling robot HTR has hands 211 arranged in the vertical direction at a pitch of 10 mm. Therefore, the handling robot HTR can grip all of the substrates W in the carrier C1 at one time.

FIG. 16D illustrates a state when about half of the substrates W gripped by the handling robot HTR is transferred to the HVC posture converter 23. The handling robot HTR causes the hands 211 to enter between the pair of placing rods 231 in the HVC posture converter 23. Then, the placing rod 231 supports a part of the substrates W conveyed by the flat plate 233. Specifically, the placing rod 231 selectively supports the substrates W conveyed by the handling robot HTR such that the substrates W to be supported and the substrates W not to be supported are alternately arranged. The substrates W to be supported are arranged at a pitch of 20 mm. The substrates W not to be supported are also arranged at a pitch of 20 mm. The substrates W to be supported and the substrates W not to be supported adjacent to each other are separated by 10 mm.

The handling robot HTR partially releases the gripping of the substrates W. That is, the gripping of the substrates W by the handling robot HTR is released with respect to the substrates W to be supported on the placing rod 231. In this way, the substrates W arranged at a pitch of 20 mm are transferred from the handling robot HTR to the HVC posture converter 23.

On the other hand, the gripping of the substrate W by the handling robot HTR is not released with respect to the substrate W not to be supported on the placing rod 321.

FIG. 16D illustrates a state in which the handling robot HTR then retracts the hands 211 from the HVC posture converter 23. Such a measure is performed to ensure that the hands 211 does not hinder the upright positioning of the substrates W during the upcoming posture conversion of the substrates W. The handling robot HTR retracts the hands 211 from the HVC posture converter 23 while gripping the substrates W not to be supported. On the other hand, the substrate W to be supported is left behind in the HVC posture converter 23 by the movement of the hands 211. Among them, since the substrates W transferred to the HVC posture converter 23 are arranged at a pitch of 20 mm, it can be handled equivalently to the substrates W supported by the HVC posture converter 23 described with reference to FIGS. 11A to 11P. That is, the same operation as the batch assembly described in the embodiment can be performed using these substrates W.

In FIG. 16D, the substrate W not to be supported left behind in the handling robot HTR is transferred to the HVC posture converter 23 at another opportunity when the substrate W comes.

FIG. 16E illustrates a state in which the HVC posture converter 23 in the state of FIG. 16D has finished transferring the substrates W to the pusher 251. Since all of the flat plates 233 of the placing rod 231 are in an empty state not supporting the substrates W, it is possible to receive the substrates W left behind in the handling robot HTR at present.

FIG. 16F illustrates a state when the remaining substrate W gripped by the handling robot HTR is transferred to the HVC posture converter 23. The handling robot HTR causes the hands 211 to enter between the pair of placing rods 231 in the HVC posture converter 23. The remaining substrates W are arranged at a pitch of 20 mm in the handling robot HTR, and the flat plates 233 are arranged at a pitch of 20 mm in the placing rod 231. Therefore, the handling robot HTR can transfer all of the remaining substrates W to the HVC posture converter 23. Since the substrates W transferred to the HVC posture converter 23 are arranged at a pitch of 20 mm, it can be handled equivalently to the substrates W supported by the HVC posture converter 23 described with reference to FIGS. 11A to 11P. That is, the same operation as the batch assembly described in the embodiment can be performed using these substrates W.

At the time of the second transfer of the substrates W described with reference to FIG. 16E, the hands 211 is moved to a position higher by 10 mm than the height at the time of the first transfer of the substrates W described with reference to FIG. 16D. Then, the hands 211 horizontally moves from the place and enters the HVC posture converter 23. In this way, when the substrate W is transferred, the transfer of the substrate W can be reliably performed without the standby placing rod 231 holding an empty space.

As described above, according to the present modification, in the process of once extracting all the substrates W from the carrier C and converting the substrates from the horizontal posture to the vertical posture, every other substrate is extracted. In this way, the substrates W to be supported in which the substrates W arranged at a pitch of 10 mm are arranged at a pitch of 20 mm and the substrates W not to be supported in which the substrates W are arranged at a pitch of 20 mm are separated. Incidentally, the initial substrate W0, the second substrate W2, and the fourth substrate W4 are the substrates W to be supported, and the first substrate W1, the third substrate W3, and the fifth substrate W5 are the substrates W not to be supported. With such a configuration, each substrate can be reliably produced.

What is claimed is:

1. A substrate processing method for collectively processing a plurality of substrates, the substrate processing method comprising:
a substrate group generation process of extracting a plurality of substrates from a carrier in which substrates defined on a front surface and a back surface are arranged at a specific pitch, and generating a substrate group in which the substrates are arranged in one direction at a pitch twice the specific pitch; and
a processing process of immersing a batch lot in a processing liquid after generating the batch lot by performing, in an arbitrary order, each of assembly processes including
a first assembly process of positioning a first substrate at a first position among the first position, a second position, a third position, a fourth position, and a fifth position that divide the predetermined interval in the substrate group into six by combining a first arrangement in which the first substrate oriented in an opposite direction to the one direction is arranged at a predetermined interval that is twice the specific pitch with the substrate group,
a second assembly process of positioning a second substrate at the second position by combining a second arrangement in which the second substrate oriented in the one direction is arranged at the predetermined interval with the substrate group,
a third assembly process of positioning a third substrate at the third position by combining a third arrangement in which the third substrate oriented in the opposite direction is arranged at the predetermined interval with the substrate group,
a fourth assembly process of positioning a fourth substrate at the fourth position by combining a fourth arrangement in which the fourth substrate oriented in the one direction is arranged at the predetermined interval with the substrate group, and
a fifth assembly process of positioning a fifth substrate at the fifth position by combining a fifth arrangement in which the fifth substrate oriented in the opposite direction is arranged at the predetermined interval with the substrate group.

2. The substrate processing method according to claim 1, wherein
a front surface of the first substrate in the first assembly process faces a front surface of the substrate group,
a back surface of the second substrate in the second assembly process faces a back surface of the first substrate,
a front surface of the third substrate in the third assembly process faces a front surface of the second substrate,
a back surface of the fourth substrate in the fourth assembly process faces a back surface of the third substrate, and
a front surface of the fifth substrate in the fifth assembly process faces a front surface of the fourth substrate, and a back surface of the fifth substrate faces a back surface of the substrate group.

3. The substrate processing method according to claim 1, wherein
the first assembly process is performed after half-rotating the first arrangement in which the first substrate oriented in the one direction is arranged at the predetermined interval,
the third assembly process is performed after half-rotating the third arrangement in which the third substrate oriented in the one direction is arranged at the predetermined interval, and
the fifth assembly process is performed after half-rotating the fifth arrangement in which the fifth substrate oriented in the one direction is arranged at the predetermined interval.

4. The substrate processing method according to claim 1, wherein a distance from the first position to the second position is ⅓ of the specific pitch in the carrier.

5. The substrate processing method according to claim 1, wherein each assembly process is performed in the order of the first assembly process, the second assembly process, the third assembly process, the fourth assembly process, and the fifth assembly process.

6. The substrate processing method according to claim 5, wherein
the substrate group is acquired from a first carrier that houses substrates in which substrates in a horizontal posture are arranged in a vertical direction,
the first arrangement is acquired from the first carrier,
the second arrangement is acquired from a second carrier that houses substrates in which substrates in the horizontal posture are arranged in the vertical direction,
the third arrangement is acquired from the second carrier,
the fourth arrangement is acquired from a third carrier that houses substrates in which substrates in the horizontal posture are arranged in the vertical direction, and
the fifth arrangement is preferably acquired from the third carrier.

7. The substrate processing method according to claim 1, wherein the predetermined interval is equally divided into six by the first position, the second position, the third position, the fourth position, and the fifth position.

8. The substrate processing method according to claim 1, wherein the substrate group generation process extracts every other substrate from the carrier to generate the substrate group.

9. The substrate processing method according to claim 1, wherein in the substrate group generation process, the substrate group is generated by extracting every other substrate in a process of converting the substrates from a horizontal posture to a vertical posture after extracting all the substrates from the carrier.
